(19) United States
(12) Patent Application Publication
(10) Pub. No.: US 2024/0376630 A1
(43) Pub. Date: Nov. 14, 2024

(54) METHODS AND DEVICES FOR PREPARING CRYSTAL CLADDINGS

(71) Applicant: MEISHAN BOYA ADVANCED MATERIALS CO., LTD., Meishan (CN)

(72) Inventors: Yu WANG, Meishan (CN); Peng GU, Meishan (CN); Zhenxing LIANG, Meishan (CN)

(73) Assignee: MEISHAN BOYA ADVANCED MATERIALS CO., LTD., Meishan (CN)

(21) Appl. No.: 18/781,924

(22) Filed: Jul. 23, 2024

Related U.S. Application Data
(63) Continuation-in-part of application No. 18/416,849, filed on Jan. 18, 2024.
Application No. 18/416,849 is a continuation of application No. PCT/CN2022/106432, filed on Jul. 19, 2022.
(63) Continuation-in-part of application No. 17/448,042, filed on Sep. 17, 2021.
Application No. 17/448,042 is a continuation of application No. 17/340,083, filed on Jun. 6, 2021, now Pat. No. 11,136,690.

(30) Foreign Application Priority Data
Jun. 10, 2020 (CN) 202010524188.5
Jul. 19, 2021 (CN) 202110814718.4

(51) Int. Cl. C30B 7/10; C30B 7/14; C30B 29/28; H01S 3/067; H01S 3/16

(52) U.S. Cl. CPC C30B 7/10; C30B 7/14; C30B 29/28; H01S 3/06708; H01S 3/1643

(57) ABSTRACT

Disclosed are a method and a device for preparing a crystal cladding. The method may include preparing an amorphous material; melting the amorphous material to form an amorphous melt; submerging an optical fiber core in the amorphous melt; forming an amorphous cladding around a periphery of the optical fiber core; and obtaining the crystal cladding by performing a crystallization process on the amorphous cladding. The device may include an amorphous material preparation component configured to prepare an amorphous material; an amorphous cladding preparation component configured to melt the amorphous material to form an amorphous melt, submerge an optical fiber core in the amorphous melt, and form an amorphous cladding around a periphery of the optical fiber core based on the amorphous melt and the optical fiber core; and a crystal cladding preparation assembly configured to perform a crystallization process on the amorphous cladding to obtain a crystal cladding.

### CROSS-REFERENCE TO RELATED APPLICATION

This application is a Continuation-in-Part of U.S. application Ser. No. 18/416,849, filed on Jan. 18, 2024, and U.S. application Ser. No. 17/448,042, filed on Sep. 17, 2021, wherein U.S. application Ser. No. 18/416,849 is a Continuation of International Application No. PCT/CN2022/106432, filed on Jul. 19, 2022, which claims priority to Chinese Patent Application No. 202110814718.4, filed on Jul. 19, 2021, and U.S. application Ser. No. 17/448,042 is a continuation of U.S. application Ser. No. 17/340,083 (issued as U.S. Pat. No. 11,136,690), filed on Jun. 6, 2021, which claims priority to Chinese Patent Application No. 202010524188.5 filed on Jun. 10, 2020, the entire contents of each of which are incorporated herein by reference.

### TECHNICAL FIELD

The present disclosure relates to the technical field of a crystal optical fiber, and in particular, to a method and a device for preparing a crystal cladding.

### BACKGROUND

A laser with a fiber structure is widely used in the fields of optoelectronics, optical communication, and superconducting technology due to its excellent performance. A crystal fiber, combining the advantages of a crystal and an optical fiber, exhibits even better performances such as a higher mechanical strength, a higher thermal conductivity, a higher pumping efficiency, a higher beam quality, a lower transmission loss, etc. A crystal cladding on an outer surface of a single-crystal fiber core can enclose an optical signal to propagate within the core, which further improves a laser performance of the crystal optical fiber. Existing techniques for preparing the crystal cladding are a high device requirement and involve considerable operational complexity. Therefore, it is desirable to provide a method and a device for preparing a crystal cladding, which can easily and quickly prepare the crystal cladding.

### SUMMARY

One of the embodiments of the present disclosure provides a method for preparing a crystal cladding. The method may include preparing an amorphous material; melting the amorphous material to form an amorphous melt; submerging an optical fiber core in the amorphous melt; forming an amorphous cladding around a periphery of the optical fiber core based on the amorphous melt and the optical fiber core; and obtaining the crystal cladding by performing a crystallization process on the amorphous cladding.

One of the embodiments of the present disclosure provides a device for preparing the crystal cladding. The device may include an amorphous material preparation component, an amorphous cladding preparation component, and a crystal cladding preparation assembly. The amorphous material preparation component may be configured to prepare the amorphous material. The amorphous cladding preparation component may be configured to melt the amorphous material to form the amorphous melt, submerge the optical fiber core in the amorphous melt, and form the amorphous cladding around the periphery of the optical fiber core. The crystal cladding preparation assembly may be configured to perform the crystallization process on the amorphous cladding to obtain the crystal cladding.

### BRIEF DESCRIPTION OF THE DRAWINGS

The present disclosure will be further illustrated by way of exemplary embodiments, which will be described in detail using the accompanying drawings. These embodiments are not limiting, and in these embodiments, the same numbering denotes the same structure, wherein:

FIG. 1 is a flowchart illustrating an exemplary process for preparing a doped YAG single crystal fiber core according to some embodiments of the present disclosure;

FIG. 2 is a flowchart illustrating an exemplary process for preparing a doped YAG single crystal fiber according to some embodiments of the present disclosure;

FIG. 3 is a schematic diagram illustrating an exemplary device for preparing a fiber core according to some embodiments of the present disclosure;

FIG. 4 is a schematic diagram illustrating an exemplary device for preparing a fiber according to some embodiments of the present disclosure;

FIG. 5 is a schematic diagram illustrating an exemplary doped YAG crystal rod according to some embodiments of the present disclosure;

FIG. 6A is a schematic diagram illustrating an exemplary doped YAG single crystal fiber core without polishing according to some embodiments of the present disclosure;

FIG. 6B is a schematic diagram illustrating an exemplary polished doped YAG single crystal fiber core according to some embodiments of the present disclosure;

FIG. 7 is a schematic diagram illustrating an exemplary bending performance test of a polished Nd:YAG single crystal fiber core according to some embodiments of the present disclosure;

FIG. 8A is a schematic diagram illustrating an exemplary doped YAG single crystal fiber core without polishing according to some embodiments of the present disclosure;

FIG. 8B is a schematic diagram illustrating an exemplary polished doped YAG single crystal fiber core according to some embodiments of the present disclosure; and

FIG. 9 is a schematic diagram illustrating an exemplary bending performance test of a polished Nd:YAG single crystal fiber core according to some embodiments of the present disclosure.

FIG. 10 is a flowchart illustrating an exemplary process for preparing a crystal cladding according to some embodiments of the present disclosure;

FIG. 11 is a schematic diagram illustrating an exemplary device for preparing a crystal cladding according to some embodiments of the present disclosure;

FIG. 12 is a schematic diagram illustrating an exemplary structure of a melt assembly according to some embodiments of the present disclosure;

FIG. 13 is a schematic diagram illustrating an exemplary structure of a dispersing and cooling assembly according to some embodiments of the present disclosure;

FIG. 14A is a schematic diagram illustrating an exemplary structure of a clamping assembly according to some embodiments of the present disclosure;

FIG. 14B is a schematic diagram illustrating an exemplary structure of a clamping assembly according to other embodiments of the present disclosure;

FIG. 15A is a schematic diagram illustrating an exemplary structure of a power element according to some embodiments of the present disclosure; and

FIG. 15B is a schematic diagram illustrating an exemplary structure of an arc discharge element according to some embodiments of the present disclosure.

In the drawings: 300 represents a device for preparing a fiber core, 310 represents a container, 331 represents a first hole, 332 represents a second hole, 340 represents a doped YAG crystal rod, and 350 represents a stirring magneton. 400 represents a device for preparing a fiber, 410 represents a growth chamber, 411 represents a growth zone, 412 represents a dissolution zone, 413 represents a doped YAG single crystal fiber core, 414 represents a raw material, 415 represents a baffle, 416 represents a fixing assembly, 417 represents a supporting assembly, 420 represents a safety device, 430 represents a two-stage heating device, 431 represents a first heating device, 432 represents a second heating device, and 433 represents a thermal insulation layer. 710 represents a polished Nd:YAG single crystal fiber core according to some embodiments of the present disclosure, and 720 represents a stainless steel rod 910 represents a polished Nd:YAG single crystal fiber core according to some embodiments of the present disclosure, and 920 represents a stainless steel rod. 1100 denotes a device for preparing a crystal cladding, 1110 denotes an amorphous material preparation component, 1111 denotes a melt assembly, 1111-1 denotes a main cavity, 1111-11 denotes a cavity upper cover, 1111-111 denotes a boss, 1111-12 denotes a cavity lower cover, 1111-121 denotes a cavity lower plate, 1111-1211 denotes an opening, 1111-122 denotes a cavity lower cover support, 1111-123 denotes a cavity lower cover body, 1111-1231 denotes a pull tab, 1111-13 denotes a middle cavity, 1111-2 denotes a melt cavity, 1111-3 denotes a heating element, 1111-4 denotes a moving element, 1111-41 denotes a connecting rod, 1112 denotes a dispersing and cooling assembly, 1112-1 denotes an ejecting element, 1112-11 denotes an ejection port, 1112-2 denotes a collecting element, 1112-21 denotes a collecting body, 1112-211 denotes a collection port, 1112-212 denotes a hole, 1112-22 denotes a collecting frame, 1112-23 denotes a baffle plate, 1112-3 denotes an oscillating element, 1120 denotes an amorphous cladding preparation component, 1121 denotes a clamping assembly, 1121-1 denotes a clamping element, 1121-2 denotes an adjusting element, 1121-3 denotes a fixing element, 1130 denotes a crystal cladding preparation component, 1131 denotes an arc discharge assembly, 1131-1 denotes a power element, 1131-11 denotes an up-and-down movement driving member, 1131-111 denotes a support, 1131-112 denotes a screw, 1131-113 denotes a slider, 1131-114 denotes a first driving motor, 1131-12 denotes a rotational movement driving member, 1131-121 denotes a support bracket, 1131-122 denotes a connecting member, 1131-123 denotes a stabilizing member, 1131-124 denotes a second driving motor, 1131-2 denotes an arc discharge element, 1140 denotes a monitoring component, 1150 denotes a controlling component, 1160 denotes a displaying component, and 1170 denotes a storing component.

### DETAILED DESCRIPTION

In order to more clearly illustrate the technical solutions of the embodiments of the present disclosure, the accompanying drawings required to be used in the description of the embodiments will be briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit,” and/or “module” as used herein are a way to distinguish between different components, elements, parts, sections, or assemblies at different levels. However, the words may be replaced by other expressions if other words accomplish the same purpose.

As shown in the present disclosure and the claims, unless the context suggests an exception, the words “one,” “an,” “a,” “one kind,” and/or “the” do not refer specifically to the singular, but may also include the plural. Generally, the terms “including” and “comprising” suggest only the inclusion of clearly identified steps and elements that do not constitute an exclusive list, and the method or device may also include other steps or elements.

Flowcharts are used in the present disclosure to illustrate operations performed by a system by embodiments of the present disclosure. It should be appreciated that the preceding or following operations are not necessarily performed in an exact sequence. Instead, the operations may be processed in a reverse order or simultaneously. Also, it is possible to add other operations to these processes, or to omit one or operation from these processes.

Some embodiments of the present disclosure provide methods for preparing a doped Yttrium Aluminum Garnet (YAG) single crystal fiber including a doped YAG single crystal fiber core and crystal cladding. A doped YAG crystal rod may be prepared by performing an operation on a doped YAG crystal ingot. The operation may include at least one of a cutting operation, a grinding operation, a polishing operation, or the like, or any combination thereof. A doped YAG single crystal fiber core may be prepared by immersing at least a portion of the doped YAG crystal rod in an acid solution and reacting for a preset time under a preset condition. The doped YAG single crystal fiber core may be placed into a growth zone of a growth chamber, and a raw material (e.g., an yttrium oxide (Y₂O₃) powder, an aluminum oxide (Al₂O₃) powder) may be placed into a dissolution zone of the growth chamber. A mineralizer (e.g., a potassium carbonate (K₂CO₃) solution, a sodium carbonate (Na₂CO₃) solution, a potassium fluoride (KF) solution, an ammonium fluoride (NH₄F) solution, a potassium hydroxide (KOH) solution, or a sodium hydroxide (NaOH) solution) may be added into the growth chamber to cause the mineralizer to immerse the raw material and the doped YAG single crystal fiber core. The growth zone and the dissolution zone may be heated by a two-stage heating device, respectively, and a doped YAG single crystal fiber may be prepared by growing a crystal cladding (e.g., a YAG single crystal cladding or a YAG polycrystal cladding) on a surface of the doped YAG single crystal fiber core based on the doped YAG single crystal fiber core and the raw material under a preset pressure. A crystal fiber may be prepared by forming an amorphous cladding around a periphery of the single crystal fiber core and performing a crystallization process on the amorphous cladding. Further, a doped YAG single crystal fiber core with a uniform diameter may be prepared by performing a cylindrical surface polishing operation on the doped YAG single crystal fiber core, which may improve a surface smoothness of the doped YAG single crystal fiber core, reduce a surface roughness of the doped YAG single crystal fiber core, reduce a transmission loss of the doped YAG single crystal fiber, and improve a transmission quality of the doped YAG single crystal fiber. The doped YAG single crystal fiber prepared according to some embodiments of the present disclosure has a smooth surface, a uniform diameter, a relatively high thermal conductivity, and a relatively high transmission quality.

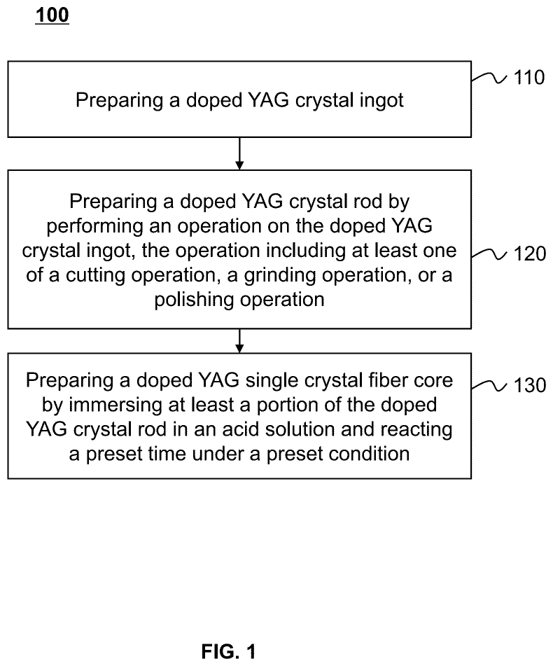

FIG. 1 is a flowchart illustrating an exemplary process for preparing a doped YAG single crystal fiber core according to some embodiments of the present disclosure. In some embodiments, process 100 may be executed automatically by a control system. For example, the process 100 may be implemented by a control instruction. The control system may control one or more devices to complete one or more operations of the process 100 based on the control instruction. In some embodiments, the process 100 may be executed semi-automatically. For example, one or more operations of the process 100 may be manually executed by an operator. In some embodiments, the process 100 may be accomplished with one or more additional operations not described, and/or without one or more of the operations discussed. Additionally, the order in which the operations of the process 100 as illustrated in FIG. 1 and described below is not intended to be limiting.

In 110, a doped YAG ingot may be prepared. In some embodiments, a diameter of the doped YAG ingot may be in a range of 20 mm-80 mm. In some embodiments, the diameter of the doped YAG ingot may be in a range of 25 mm-70 mm. In some embodiments, the diameter of the doped YAG ingot may be in a range of 30 mm-60 mm. In some embodiments, the diameter of the doped YAG ingot may be in a range of 35 mm-50 mm. In some embodiments, the diameter of the doped YAG ingot may be in a range of 40 mm-45 mm.

In some embodiments, a length of the doped YAG ingot may be in a range of 80 mm-160 mm. In some embodiments, the length of the doped YAG ingot may be in a range of 90 mm-155 mm. In some embodiments, the length of the doped YAG ingot may be in a range of 100 mm-150 mm. In some embodiments, the length of the doped YAG ingot may be in a range of 110 mm-140 mm. In some embodiments, the length of the doped YAG ingot may be in a range of 120 mm-130 mm.

In some embodiments, a doped element doped in the doped YAG ingot may include chromium (Cr), neodymium (Nd), holmium (Ho), erbium (Er), thulium (Tm), ytterbium (Yb), or the like, or any combination thereof. In some embodiments, a doped concentration of the doped element in the doped YAG ingot may be in a range of 1%-4%. In some embodiments, the doped concentration of the doped element may be in a range of 1.5%-3.5%. In some embodiments, the doped concentration of the doped element may be in a range of 2%-3%. In some embodiments, the doped concentration of the doped element may be in a range of 2.2%-2.6%. As used herein, the doped concentration of the doped element in the doped YAG ingot refers to an amount of Y³⁺ lattice sites in YAG occupied by the doped element through substitutional doping. For example, a molecular formula of the doped YAG may be expressed as (XₓY_{1-X})₃Al₅O₁₂, wherein X denotes the doped element and x denotes the doped concentration of the doped element.

In some embodiments, the doped YAG crystal ingot may be prepared by a crystal growth technique (e.g., a Czochralski technique, a hydrothermal technique, a region melting technique, a sublimation technique, an epitaxial growth technique). Merely by way of example, the YAG crystal ingot may be prepared according to the Czochralski technique. In some embodiments, the Czochralski technique may include operations including material melting, seed crystal preheating, seed crystal introducing, temperature adjustment, necking, shoulder release, equal diameter growth, ending, cooling, crystal extraction, etc. In some embodiments, during a lifting process, a flowing gas may be also introduced to prevent oxide particles generated by an oxidation of a portion of an iridium-gold crucible in a crystal growth device from adhering to a surface of the YAG crystal ingot, thereby affecting a quality of the YAG crystal ingot. In some embodiments, a flowing rate of the flowing gas may be in a range of 3 mL/min-6 mL/min. In some embodiments, the flowing gas may include an inert gas (e.g., helium, argon), nitrogen, a mixed gas including an inert gas and oxygen, a mixed gas including nitrogen and oxygen, etc. In some embodiments, a volume ratio of oxygen in the mixed gas may be in a range of 4%-6%. In some embodiments, the volume ratio of oxygen in the mixed gas may be in a range of 4.5%-5%. More descriptions of the Czochralski technique may be found in the International Patent Application No. PCT/CN2019/101693, filed on Aug. 21, 2019, and the International Patent Application No. PCT/CN2019/101691, filed on Aug. 21, 2019, the contents of each of which are incorporated herein by reference.

In 120, a doped YAG crystal rod may be prepared by performing an operation on the doped YAG crystal ingot. The operation may include at least one of a cutting operation, a grinding operation, a polishing operation, or the like, or any combination thereof.

As used herein, the cutting operation refers to cutting off the doped YAG crystal ingot with a tool (e.g., a machine tool) under a preset condition (e.g., a preset pressure) to make a size of the doped YAG crystal ingot reach a predetermined size (a product may be referred to as “a cutting intermediate”). The grinding operation refers to processing a surface of an object to be ground (e.g., the doped YAG crystal ingot or the cutting intermediate) through a relative movement between a grinding tool and the object to be ground under a preset pressure (a product may be referred to as “a grinding intermediate”). The polishing operation refers to processing a surface of an object to be polished (e.g., the doped YAG crystal ingot, the cutting intermediate, or the grinding intermediate) with a polishing medium to reduce a roughness of the object to be polished, thereby making the surface of the object to be polished smooth.

In some embodiments, a diameter of the doped YAG crystal rod may be smaller than a preset diameter threshold. For example, the diameter of the doped YAG crystal rod may be in a range of 1 mm to 2 mm. In some embodiments, the diameter of the doped YAG crystal rod may be in a range of 1.2 mm to 1.8 mm. In some embodiments, the diameter of the doped YAG crystal rod may be in a range of 1.4 mm to 1.6 mm.

In some embodiments, a length of the doped YAG crystal rod may be less than a preset length threshold. For example, the length of the YAG crystal rod may be in a range of 3 cm to 5 cm. In some embodiments, the length of the YAG crystal rod may be in a range of 3.2 cm to 4.8 cm. In some embodiments, the length of the YAG crystal rod may be in a range of 3.4 cm to 4.6 cm. In some embodiments, the length of the YAG crystal rod may be in a range of 3.6 cm to 4.4 cm. In some embodiments, the length of the YAG crystal rod may be in a range of 3.8 cm to 4.2 cm.

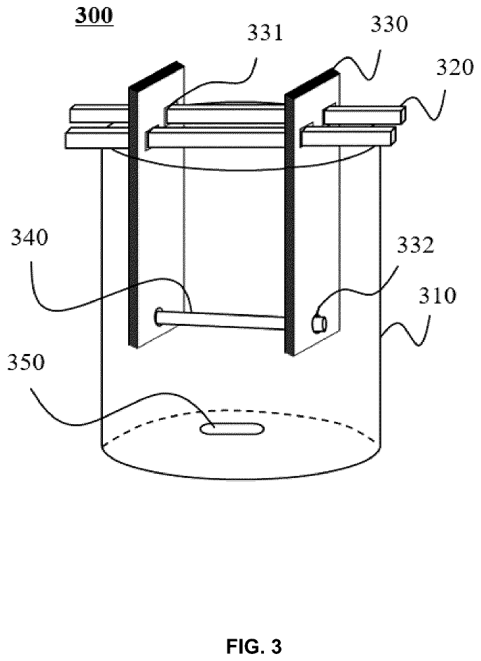

In 130, a doped YAG single crystal fiber core may be prepared by immersing at least a portion of the doped YAG crystal rod into an acid solution and reacting for a preset time under a preset condition. In some embodiments, operation 130 may be implemented by a fiber core preparation device shown in FIG. 3.

In some embodiments, a diameter of the doped YAG single crystal fiber core may be in a range of 80 μm-220 μm. In some embodiments, the diameter of the doped YAG single crystal fiber core may be in a range of 100 μm-200 μm. In some embodiments, the diameter of the doped YAG single crystal fiber core may be in a range of 120 μm-180 μm. In some embodiments, the diameter of the doped YAG single crystal fiber core may be in a range of 140 μm-160 μm. In some embodiments, the diameter of the doped YAG single crystal fiber core may be 150 μm.

In some embodiments, a length of the doped YAG single crystal fiber core may be in a range of 20 mm-40 mm. In some embodiments, the length of the doped YAG single crystal fiber core may be in a range of 25 mm-35 mm. In some embodiments, the length of the doped YAG single crystal fiber core may be in a range of 28 mm-32 mm. In some embodiments, the length of the doped YAG single crystal fiber core may be 30 mm.

In some embodiments, the acid solution may include a concentrated phosphoric acid solution, a concentrated sulfuric acid solution, a concentrated hydrochloric acid solution, or the like, or any combination thereof.

In some embodiments, a mass fraction of solute in the concentrated phosphoric acid solution (also can be referred to as a mass fraction of the concentrated phosphoric acid solution for brevity) may be in a range of 85% to 90%. In some embodiments, the mass fraction of the concentrated phosphoric acid solution may be in a range of 86% to 89%. In some embodiments, the mass fraction of the concentrated phosphoric acid solution may be in a range of 87% to 88%.

In some embodiments, a mass fraction of solute in the concentrated sulfuric acid solution (also can be referred to as a mass fraction of the concentrated sulfuric acid solution for brevity) may be in a range of 67% to 98%. In some embodiments, the mass fraction of the concentrated sulfuric acid solution may be in a range of 70% to 95%. In some embodiments, the mass fraction of the concentrated sulfuric acid solution may be in a range of 73% to 92%. In some embodiments, the mass fraction of the concentrated sulfuric acid solution may be in a range of 75% to 90%. In some embodiments, the mass fraction of the concentrated sulfuric acid solution may be in a range of 77% to 88%. In some embodiments, the mass fraction of the concentrated sulfuric acid solution may be in a range of 80% to 85%.

In some embodiments, a mass fraction of solute in the concentrated hydrochloric acid solution (also can be referred to as a mass fraction of the concentrated hydrochloric acid solution for brevity) may be in a range of 36% to 38%.

Merely by way of example, the acid solution may be a mixed solution including a concentrated sulfuric acid solution and a concentrated sulfuric acid solution, wherein a mass fraction of the concentrated phosphoric acid solution may be in a range of 85% to 90%, a mass fraction of the concentrated sulfuric acid solution may be in a range of 67% to 98%, and a volume ratio of the concentrated phosphoric acid solution and the concentrated sulfuric acid solution may be in a range of 1:(1˜4) (e.g., 1:1, 1:1.5, 1:2, 1:3, 1:4).

In some embodiments, the preset condition may include a preset temperature and a preset magnetic stirring rate. In some embodiments, the preset temperature may be in a range of 140° C. to 360° C. In some embodiments, the preset temperature may be in a range of 160° C. to 340° C. In some embodiments, the preset temperature may be in a range of 180° C. to 320° C. In some embodiments, the preset temperature may be in a range of 200° C. to 300° C. In some embodiments, the preset temperature may be in a range of 210° C. to 290° C. In some embodiments, the preset temperature may be in a range of 220° C. to 280° C. In some embodiments, the preset temperature may be in a range of 230° C. to 270° C. In some embodiments, the preset temperature may be in a range of 240° C. to 260° C. In some embodiments, the preset temperature may be 250° C.

In some embodiments, the preset magnetic stirring rate may be in a range of 150 rpm to 350 rpm. In some embodiments, the preset magnetic stirring rate may be in a range of 180 rpm to 320 rpm. In some embodiments, the preset magnetic stirring rate may be in a range of 200 rpm to 300 rpm. In some embodiments, the preset magnetic stirring rate may be in a range of 210 rpm to 290 rpm. In some embodiments, the preset magnetic stirring rate may be in a range of 220 rpm to 280 rpm. In some embodiments, the preset magnetic stirring rate may be in a range of 230 rpm to 270 rpm. In some embodiments, the preset magnetic stirring rate may be in a range of 240 rpm to 260 rpm. In some embodiments, the preset magnetic stirring rate may be 250 rpm.

In some embodiments, the preset time may be in a range of 4 h to 8 h. In some embodiments, the preset time may be in a range of 4.5 h to 7.5 h. In some embodiments, the preset time may be in a range of 5 h to 7 h. In some embodiments, the preset time may be in a range of 5.5 h to 6.5 h. In some embodiments, the preset time may be 6 h.

In some embodiments, the doped YAG single crystal fiber core may be rinsed using a cleaning solution to remove the acid solution remaining on a surface of the doped YAG single crystal fiber core. In some embodiments, the cleaning solution may include ethanol, water, methanol, N-propanol, isopropanol, acetone, or the like, or any combination thereof. In some embodiments, the rinsed doped YAG single crystal fiber core may be dried to remove the cleaning solution remaining on the surface of the doped YAG single crystal fiber core.

In some embodiments, the doped YAG single crystal fiber core may be polished using a polishing liquid to improve a surface smoothness of the doped YAG single crystal fiber core and reduce a surface roughness of the doped YAG single crystal fiber core. During a polishing process, a cylindrical surface polishing operation may be performed on the doped YAG single crystal fiber core. In some embodiments, the cylindrical surface polishing operation may be performed by stirring the polishing liquid using a stirrer (e.g., a magnetic stirrer, a mechanical stirrer, an ultrasound mixer) at a preset stirring rate. In some embodiments, the stirrer may be equipped with a temperature control device which is configured to control a temperature of the polishing liquid.

In some embodiments, the preset stirring rate (e.g., a preset magnetic stirring rate) may be in a range of 200 rpm to 600 rpm. In some embodiments, the preset stirring rate may be in a range of 250 rpm to 550 rpm. In some embodiments, the preset stirring rate may be in a range of 280 rpm to 520 rpm. In some embodiments, the preset stirring rate may be in a range of 300 rpm to 500 rpm. In some embodiments, the preset stirring rate may be in a range of 320 rpm to 480 rpm. In some embodiments, the preset stirring rate may be in a range of 350 rpm to 450 rpm. In some embodiments, the preset stirring rate may be in a range of 370 rpm to 420 rpm. In some embodiments, the preset stirring rate may be 400 rpm.

In some embodiments, the temperature of the polishing liquid may be within a predetermined temperature range. In some embodiments, the temperature range may be 20° C. to 150° C. In some embodiments, the temperature range may be 25° C. to 130° C. In some embodiments, the temperature range may be 30° C. to 100° C. In some embodiments, the temperature range may be 40° C. to 90° C. In some embodiments, the temperature range may be 50° C. to 80° C. In some embodiments, the temperature range may be 60° C. to 70° C. In some embodiments, the temperature of the polishing liquid may be 65° C.

In some embodiments, the polishing liquid may include a polishing powder. In some embodiments, a mass fraction of the polishing powder in the polishing liquid may be in a range of 3% to 20%. In some embodiments, the mass fraction of the polishing powder in the polishing liquid may be in a range of 4% to 15%. In some embodiments, the mass fraction of the polishing powder in the polishing liquid may be in a range of 5% to 10%. In some embodiments, the mass fraction of the polishing powder in the polishing liquid may be in a range of 5.5% to 9.5%. In some embodiments, the mass fraction of the polishing powder in the polishing liquid may be in a range of 6% to 9%. In some embodiments, the mass fraction of the polishing powder in the polishing liquid may be in a range of 6.5% to 8.5%. In some embodiments, the mass fraction of polishing powder in the polishing liquid may be in a range of 7% to 8%.

In some embodiments, a particle diameter of the polishing powder may be in a range of 20 nm to 200 nm. In some embodiments, the particle diameter of the polishing powder may be in a range of 30 nm to 180 nm. In some embodiments, the particle diameter of the polishing powder may be in a range of 40 nm to 150 nm. In some embodiments, the particle diameter of the polishing powder may be in a range of 50 nm to 100 nm. In some embodiments, the particle diameter of the polishing powder may be in a range of 55 nm to 95 nm. In some embodiments, the particle diameter of the polishing powder may be in a range of 60 nm to 90 nm. In some embodiments, the particle diameter of the polishing powder may be in a range of 65 nm to 85 nm. In some embodiments, the particle diameter of the polishing powder may be in a range of 70 nm to 80 nm. In some embodiments, the particle diameter of the polishing powder may be 75 nm. In some embodiments, the polishing powder may include silicon oxide, corundum, or the like, or any combination thereof.

In some embodiments, a pH value of the polishing liquid may be adjusted using an acidic (e.g., hydrochloric acid, sulfuric acid, nitric acid, phosphoric acid) solution to cause a difference between the pH value of the polishing liquid and a preset pH value to be less than a preset threshold. Thus, a polishing effect of the polishing liquid on the doped YAG single crystal fiber core can be improved. In some embodiments, the preset pH value may be in a range of 3 to 5. In some embodiments, the preset pH value may be in a range of 3.2 to 4.8. In some embodiments, the preset pH value may be in a range of 3.4 to 4.6. In some embodiments, the preset pH value may be in a range of 3.6 to 4.4. In some embodiments, the preset pH value may be in a range of 3.8 to 4.2. In some embodiments, the preset pH value may be 4. In some embodiments, the preset threshold may be in a range of 0.1 to 0.5. In some embodiments, the preset threshold may be in a range of 0.2 to 0.4. In some embodiments, the preset threshold may be 0.3.

In some embodiments, a polishing time may be in a range of 1 min to 30 min. In some embodiments, the polishing time may be in a range of 2 min to 28 min. In some embodiments, the polishing time may be in a range of 5 min to 25 min. In some embodiments, the polishing time may be in a range of 7 min to 23 min. In some embodiments, the polishing time may be in a range of 10 min to 20 min. In some embodiments, the polishing time may be in a range of 12 min to 18 min. In some embodiments, the polishing time may be in a range of 14 min to 16 min. In some embodiments, the polishing time may be 15 min.

In some embodiments, an effect of the cyclical surface polishing operation may be adjusted by adjusting the preset stirring rate, the temperature of the polishing liquid, mass fraction of the polishing powder in the polishing liquid, a practical diameter of the polishing powder, a polishing time, or the like, or any combination thereof. In some embodiments, the cyclical surface polishing operation may be performed by using a polishing medium (e.g., a flexible medium, a viscous medium, a fluid medium) instead of a polishing liquid.

In some embodiments, the polished YAG single crystal fiber core may be further cleaned to remove the polishing liquid adhered on the surface of the doped YAG single crystal fiber core. For example, the doped YAG single crystal fiber core may be cleaned by an ultrasonic cleaning machine.

It should be noted that the above description of the process 100 is merely provided for the purposes of illustration, and not intended to limit the scope of the present disclosure. For persons having ordinary skills in the art, multiple variations and modifications on the process 100 may be made under the teachings of the present disclosure. However, those variations and modifications do not depart from the scope of the present disclosure. For example, the process 100 may be also used to prepare a polycrystalline fiber core (e.g., a ceramic fiber core). As another example, the process 100 may be further used to prepare other single crystal fiber cores, and not limited to the doped YAG single crystal fiber core.

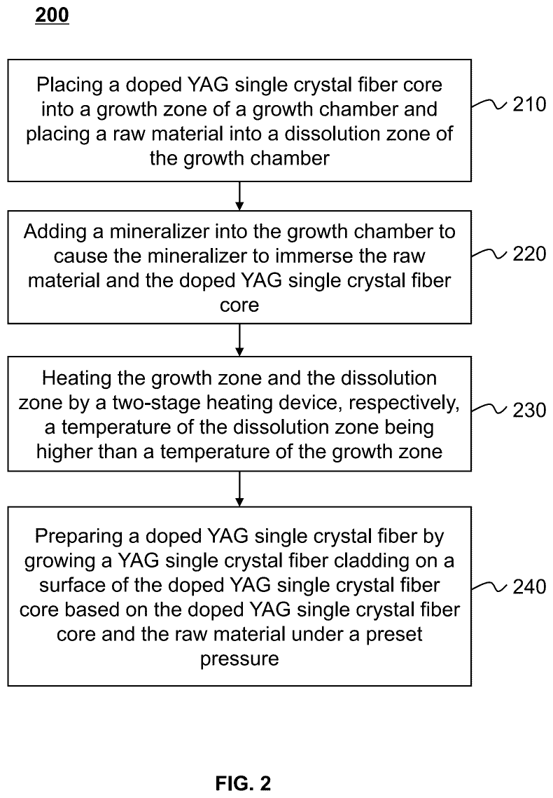

FIG. 2 is a flowchart illustrating an exemplary process for preparing a doped YAG single crystal fiber according to some embodiments of the present disclosure. In some embodiments, process 200 may be executed automatically by a control system. For example, the process 200 may be implemented by a control instruction. The control system may control one or more devices to achieve one or more operations of the process 200 based on the control instruction. In some embodiments, the process 200 may be executed semi-automatically. For example, one or more operations of the process 200 may be manually executed by an operator. In some embodiments, the process 200 may be accomplished with one or more additional operations not described, and/or without one or more of the operations discussed. Additionally, the order of the operations of the process 200 illustrated in FIG. 2 and described below is not intended to be limiting.

In 210, a doped Yttrium Aluminum Garnet (YAG) single crystal fiber core may be placed into a growth zone of a growth chamber and a raw material may be placed into a dissolution zone of the growth chamber. In some embodiments, operation 210 may be performed by a movable device (e.g., a robotic arm) or manually by an operator.

The doped YAG single crystal fiber core may be pre-prepared. In some embodiments, a doped YAG crystal rod may be prepared first, then the doped YAG single crystal fiber core may be prepared by refining the doped YAG crystal rod using an acid solution. More descriptions regarding the preparation of the doped YAG single crystal fiber core may be found elsewhere in the present disclosure (e.g., FIG. 2 and the descriptions thereof).

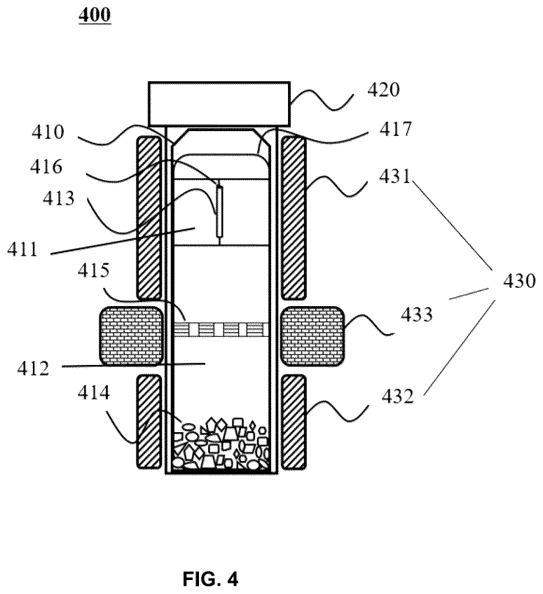

As used herein, the growth chamber refers to a place where a doped YAG single crystal fiber is prepared by growing a YAG single crystal fiber cladding on a surface of a fiber core (e.g., the doped YAG single crystal fiber core). In some embodiments, the growth chamber may include an autoclave. In some embodiments, the autoclave may be made of stainless steel, carbon manganese steel, nickel base alloy, titanium alloy, or the like, or any combination thereof. In some embodiments, a shape of the growth chamber may include a cylinder, a cuboid, a cube, a prism, etc. In some embodiments, the growth chamber may include the growth zone and the dissolution zone, which are used to place the fiber core and the raw material, respectively. In some embodiments, the growth zone may be located above the dissolution zone. In some embodiments, a volume of the growth zone may be greater than, equal to, or less than a volume of the dissolution zone. In some embodiments, a volume ratio of the growth zone to the dissolution zone may be 2:3, 3:4, 4:5, 1:1, 3:2, 4:3, 5:3, etc. More descriptions regarding the growth chamber may be found elsewhere in the present disclosure (e.g., FIG. 4 and the descriptions thereof).

The raw material may include yttrium oxide, aluminum oxide, etc. In some embodiments, a purity of the raw material may be greater than or equal to 95%, 98%, 99%, 99.9%, 99.99%, 99.999%, etc. In some embodiments, the raw material may be in a form of powder, block, granule, or the like, or any combination thereof.

In 220, a mineralizer may be added into the growth chamber to cause the mineralizer to immerse the raw material and the doped YAG single crystal fiber core. In some embodiments, operation 220 may be performed by the movable device (e.g., the robotic arm) or manually by the operator.

The mineralizer may be used to increase a dissolvability of the raw material (e.g., yttrium oxide, aluminum oxide). In some embodiments, the mineralizer may include a potassium carbonate (K₂CO₃) solution, a sodium carbonate (Na₂CO₃) solution, a potassium fluoride (KF) solution, an ammonium fluoride (NH₄F) solution, a potassium hydroxide (KOH) solution, a sodium hydroxide (NaOH) solution, or the like, or any combination thereof. In some embodiments, a concentration of the mineralizer may be in a range of 0.5 mol/L to 5 mol/L. In some embodiments, the concentration of the mineralizer may be in a range of 1 mol/L to 4 mol/L. In some embodiments, the concentration of the mineralizer may be in a range of 1.5 mol/L to 3.5 mol/L. In some embodiments, the concentration of the mineralizer may be in a range of 2 mol/L to 3 mol/L.

In 230, the growth zone and the dissolution zone may be heated by a two-stage heating device, respectively. A temperature of the dissolution zone may be higher than a temperature of the growth zone.

In some embodiments, the temperature of the dissolution zone may be 600° C. to 700° C., and the temperature of the growth zone may be 580° C. to 680° C. In some embodiments, the temperature of the dissolution zone may be 610° C. to 690° C., and the temperature of the growth zone may be 585° C. to 675° C. In some embodiments, the temperature of the dissolution zone may be 615° C. to 670° C., and the temperature of the growth zone may be 590° C. to 650° C. In some embodiments, the temperature of the dissolution zone may be 620° C. to 665° C., and the temperature of the growth zone may be 595° C. to 645° C. In some embodiments, the temperature of the dissolution zone may be 625° C. to 660° C., and the temperature of the growth zone may be 600° C. to 640° C. In some embodiments, the temperature of the dissolution zone may be 630° C. to 655° C., and the temperature of the growth zone may be 605° C. to 635° C. In some embodiments, the temperature of the dissolution zone may be 635° C. to 650° C., and the temperature of the growth zone may be 610° C. to 630° C. In some embodiments, the temperature of the dissolution zone may be 640° C. to 645° C., and the temperature of the growth zone may be 615° C. to 625° C.

As used herein, the two-stage heating device refers to a heating device including two independent heating units, and the two independent heating units may be used to heat the growth zone and the dissolution zone, respectively. In some embodiments, at least one of independent heating units may include one or more heating sub-units each of which can be configured to heat a portion of the growth zone (or the dissolution zone). In some embodiments, temperatures of different portions of the growth zone (or the dissolution zone) may be different. In some embodiments, the two independent heating units may be separated by a thermal insulation layer (e.g., a light high-alumina brick) to improve a temperature gradient between the growth zone and the dissolution zone. In some embodiments, the temperature gradient between the growth zone and the dissolution zone (or temperature gradients within the growth zone or the dissolution zone) may be adjusted by adjusting one or more heating parameters (e.g., a current, a resistance, a power) associated with the two independent heating units (or the heating sub-units). In some embodiments, the two-stage heating device may include a resistance furnace, a heating coil (e.g., a ring heating coil), an electromagnetic furnace, or the like, or any combination thereof.

In some embodiments, before the growth zone and the dissolution zone are heated by the two-stage heating device, respectively, the growth chamber may be sealed (e.g., sealed by welding). The sealed growth chamber may be placed into a safety device. The sealed growth chamber and the safety device may be sealed as a whole, and the sealed whole may be further placed into the two-stage heating device. More descriptions regarding the two-stage heating device and the safety device may be found elsewhere in the present disclosure (e.g., FIG. 4 and the descriptions thereof).

In 240, the doped YAG single crystal fiber may be prepared by growing the YAG single crystal fiber cladding on the surface of the doped YAG single crystal fiber core based on the doped YAG single crystal fiber core and the raw material under a preset pressure.

In some embodiments, the preset pressure may be in a range of 110 MPa-170 MPa. In some embodiments, the preset pressure may be in a range of 115 MPa-165 MPa. In some embodiments, the preset pressure may be in a range of 120 MPa-160 MPa. In some embodiments, the preset pressure may be in a range of 125 MPa-155 MPa. In some embodiments, the preset pressure may be in a range of 130 MPa-150 MPa. In some embodiments, the preset pressure may be in a range of 135 MPa-145 MPa. In some embodiments, the preset pressure may be 140 MPa.

As described in connection with operation 230, during a process for heating the growth zone and the dissolution zone, a portion of solvent (e.g., deionized water) of the mineralizer in the growth chamber may be constantly vaporized to cause a pressure in the growth chamber to reach the preset pressure. Meanwhile, the raw material (e.g., yttrium oxide, aluminum oxide) in the dissolution zone may be constantly dissolved in the mineralizer to form a saturated solution. Since the temperature of the dissolution zone is higher than the temperature of the growth zone, a convection of solution may be formed in the growth chamber. The saturated solution with higher temperature in the dissolution zone may be transported to the growth zone. In addition, since the temperature of the growth zone is relatively low, the saturated solution transported to the growth zone may gradually be supersaturated, so that a solute (e.g., yttrium oxide, aluminum oxide) may be constantly precipitated on the surface of the YAG single crystal fiber core. As a result, the doped YAG single crystal fiber may be prepared by growing the YAG single crystal fiber cladding with a preset thickness on the surface of the doped YAG single crystal fiber core.

It should be noted that the above description of the process 200 is merely provided for the purposes of illustration, and not intended to limit the scope of the present disclosure. For persons having ordinary skills in the art, multiple variations or modifications on the process 200 may be made under the teachings of the present disclosure. However, those variations and modifications do not depart from the scope of the present disclosure. For example, the process 200 may also be used to prepare other single crystal fibers (e.g., Yttrium Aluminum Perovskite (YAP) single crystal fibers, Lithium Yttrium Fluoride (LYF) single crystal fibers), not limited to the doped YAG single crystal fiber.

FIG. 3 is a schematic diagram illustrating an exemplary device for preparing a fiber core according to some embodiments of the present disclosure. As shown in FIG. 3, a device 300 for preparing a fiber core (also can be referred to as a “fiber core preparation device 300”) may include a container 310, a supporting rod 320, a supporting plate 330, and a magnetic stirrer (not shown in FIG. 3).

The container 310 may be used to accommodate an acidic solution. In some embodiments, the container 310 may include a glass container, a ceramic container, a plastic container, or any other container that does not chemically react with the acid solution. In some embodiments, a shape of the container 310 may include a cylinder, a cube, a rectangular cuboid, a prism, etc.

The supporting rod 320 and the supporting plate 330 may be connected to each other for supporting a doped YAG crystal rod 340. For example, the supporting rod 320 may be connected to an upper end of the supporting plate 330. Both ends of the supporting rod 320 may be disposed on the top (e.g., an opening) of the container 310, respectively. The YAG crystal rod 340 may be placed at a lower end of the supporting plate 330 and immersed in the acid solution. As shown in FIG. 3, the upper end of the supporting plate 330 may be equipped with one or more (e.g., 1, 2, 3) first holes 331. The supporting rod 320 may be connected to the supporting plate 330 through the one or more first holes 331. The lower end of the supporting plate 330 may be equipped with one or more second holes 332. The doped YAG crystal rod 340 may be connected to the supporting plate 330 through the one or more second holes 332.

In some embodiments, a count of the supporting rods 320 may be a default setting value (e.g., 1, 2, 3) or may be set according to different situations. For example, the supporting rods 320 may include two parallel rods. Similarly, a count of the supporting plates 330 may be a default setting value (e.g., 1, 2, 3) or may be set according to different situations. For example, the supporting plates 330 may include two parallel plates. In some embodiments, the supporting rod 320 may include a glass rod, a ceramic rod, a plastic rod, or any other rod that does not chemically react with the acid solution. Similarly, the supporting plate 330 may include a glass plate, a ceramic plate, a plastic plate, or any other plate that does not chemically reacted with the acid solution.

The magnetic stirrer (not shown) may be disposed at a bottom of the container 310 for stirring the acid solution, thereby accelerating the preparation of the doped YAG single crystal fiber core. In some embodiments, the magnetic stirrer may also be used to stir a polishing liquid to polish (e.g., perform a cylindrical surface polishing operation on) the doped YAG single crystal fiber core. In some embodiments, the magnetic stirrer may include a stirring magneton 350 and a power device (not shown in the figure).

FIG. 4 is a schematic diagram illustrating an exemplary device for preparing a fiber according to some embodiments of the present disclosure. As shown in FIG. 4, a device 400 for preparing a fiber (also can be referred to as a “fiber preparation device 400”) may include a growth chamber 410, a safety device 420, and a two-stage heating device 430.

The growth chamber 410 may include a growth zone 411 and a dissolution zone 412. The growth zone 411 may be configured to contain a doped YAG single crystal fiber core 413 and the dissolution zone 412 may be configured to contain a raw material 414. In some embodiments, the growth chamber 410 may further include a baffle 415 for dividing the growth zone 411 and the dissolution zone 412. The baffle 415 may have one or more holes through which a convection of solution may be formed in the growth chamber 410. In some embodiments, the baffle 415 may have a preset aperture ratio to equilibrate a convection speed of solution between the growth zone 411 and the dissolution zone 412. As used herein, an aperture ratio refers to a ratio of a total area of the one or more holes on the baffle 415 to an area of the baffle 415. In some embodiments, the preset aperture ratio may be in a range of 4% to 13%. In some embodiments, the preset aperture ratio may be in a range of 5% to 12%. In some embodiments, the preset aperture ratio may be in a range of 6% to 11%. In some embodiments, the preset aperture ratio may be in a range of 7% to 10%. In some embodiments, the preset aperture ratio may be in a range of 8% to 9%. In some embodiments, the preset aperture ratio may be in a range of 8.5%.

In some embodiments, the doped YAG single crystal fiber core 413 may be fixed into the growth chamber 410 by a fixing assembly 416 and a supporting assembly 417. In some embodiments, the fixing assembly 416 may include a silver wire, a gold wire, etc. The supporting assembly 417 may include a silver wire frame, a gold wire frame, etc.

The safety device 420 may be configured to protect the growth chamber 410. For example, a preset volume of deionized water may be filled in a gap between the safety device 420 and the growth chamber 410. When the safety device 420 is heated to a preset temperature, at least a portion of the deionized water in the gap may be vaporized to generate a certain pressure, so that the pressure inside and outside the growth chamber 410 can be balanced, thereby protecting the growth chamber 410. In some embodiments, the safety device 420 may be made of any temperature-resistant and pressure-resistant material, for example, stainless steel, carbon steel, low alloy steel, etc. In some embodiments, a shape of the safety device 420 may be the same as or different from a shape of the growth chamber 410. For example, the shape of the safety device 420 may be a cylinder, a cube, a rectangular cuboid, a prism, etc.

The two-stage heating device 430 may be configured to provide a temperature required for growing a YAG single crystal fiber cladding. In some embodiments, the two-stage heating device 430 may include a first heating device 431 and a second heating device 432. The first heating device 431 may be configured to heat the growth zone 411 and the second heating device 432 may be configured to heat the dissolution zone 412. In some embodiments, the first heating device 431 or the second heating device 432 may include a resistance furnace, a heating coil (e.g., a ring heating coil), an electromagnetic furnace, or the like, or any combination thereof. In some embodiments, the two-stage heating device 430 may further include a thermal insulation layer 433. The thermal insulation layer 433 may be disposed between the first heating device 431 and the second heating device 432 for increasing a temperature gradient of the growth zone 411 and the dissolution zone 412, thereby increasing a growth rate of the YAG single crystal fiber cladding. In some embodiments, the thermal insulation layer 433 may include a light high-alumina brick, a diatomite brick, a light clay brick, a light silicon brick, or the like, or any combination thereof.

In some embodiments, an installation of the fiber preparation device 400 may be implemented by one or more following operations.

At step 1, the raw material 414 (e.g., yttrium oxide, aluminum oxide) may be placed on a bottom (i.e., the dissolution zone 412) of the growth chamber 410.

At step 2, the baffle 415 may be placed into the growth chamber 410 to divide the growth chamber 410 into the growth zone 411 and the dissolution zone 412.

At step 3, a preset volume of a mineralizer may be added into the growth chamber 410. In some embodiments, the preset volume may be 65% to 75% of a volume of the growth chamber 410. In some embodiments, the preset volume may be 68% to 72% of the volume of the growth chamber 410. In some embodiments, the preset volume may be 70% of the volume of the growth chamber 410.

At step 4, the doped YAG single crystal fiber core 413 may be fixed to the supporting assembly 417 (e.g., a silver wire frame) by the fixing assembly 416 (e.g., a silver wire).

At step 5, the supporting assembly 417 (e.g., the silver wire frame) that is fixed with the doped YAG single crystal fiber core 413 may be put into the growth chamber 410 to cause the doped YAG single crystal fiber core 413 to locate within the growth zone 411.

At step 6, the growth chamber 410 may be sealed. For example, the growth chamber 410 may be sealed by welding.

At step 7, the sealed growth chamber 410 may be loaded into the safety device 420.

At step 8, the preset volume of the deionized water may be filled in the gap between the growth chamber 410 and the safety device 420 to balance pressures inside and outside the chamber 410, thereby protecting the growth chamber 410. In some embodiments, the preset volume may be 60% to 70% of a volume of the gap between the growth chamber 410 and the safety device 420.

At step 9, the safety device 420 may be sealed. For example, a metal ring cone may be used to seal the safety device 420.

At step 10, the sealed safety device 420 may be placed into the two-stage heating device 430 so that the first heating device 431 heats the growth zone 411 and the second heating device 432 heats the dissolution zone 412.

### Embodiment 1

A doped concentration of Nd was set as 0.01 and raw materials required for generating an Nd:YAG crystal ingot were calculated as including: 42.4 g Nd₂O₃, 2816.8 g Y₂O₃, and 2141.2 g Al₂O₃. A purity of each of the raw materials was greater than or equal to 99.99%. After the raw materials were mixed, the mixed raw material was poured into a mold and pressed into a block under a pressure of 140 MPa. The block was calcined at 1300° C. for 12 hours and an Nd:YAG block was prepared. The Nd:YAG block was placed into an iridium-gold crucible in a single crystal furnace. A YAG single crystal with a [111] orientation was used as a seed crystal. A Nd:YAG crystal ingot was prepared after single crystal furnace charging operation, vacuum pumping operation, nitrogen introducing operation, material melting operation, seed crystal preheating operation, seed crystal introducing operation, temperature adjustment operation, necking operation, shoulder release operation, equal diameter growth operation, ending operation, cooling operation, crystal extraction operation, etc. A flowing rate of flowing nitrogen was 3 mL/min. During the growth of the Nd:YAG crystal ingot, a rotational speed of the seed crystal was 15 rpm, a lifting speed of the seed crystal was 0.6 mm/h, a growth temperature was 2000° C., and a growth time was 15 days.

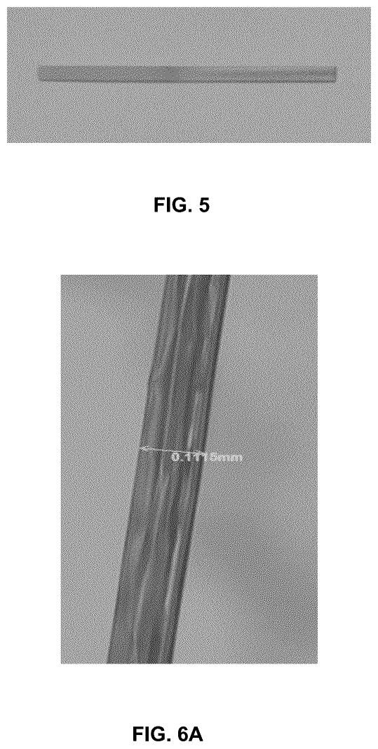

An Nd:YAG crystal rod shown in FIG. 5 was prepared by performing a cutting operation, a grinding operation, and a polishing operation on the Nd:YAG crystal ingot. The Nd:YAG crystal rod had a diameter of 1.7 mm and a length of 3 cm.

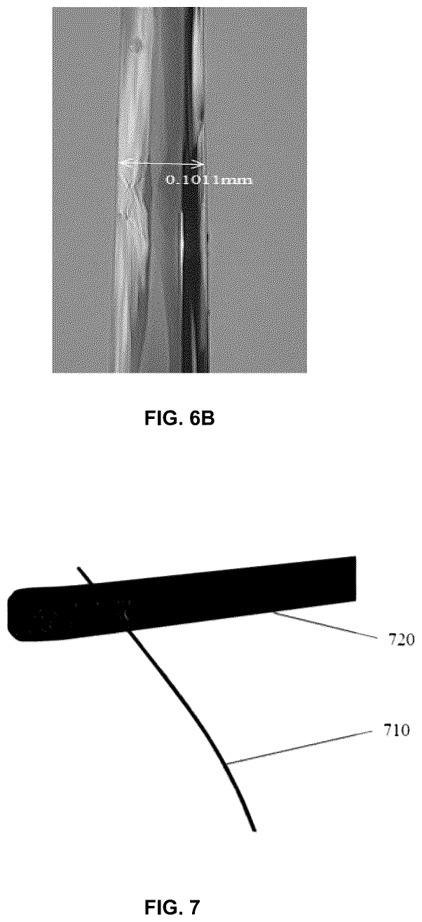

150 mL of a concentrated sulfuric acid solution with a mass fraction of 67% and 150 mL of a concentrated phosphoric acid solution with a mass fraction of 85% were mixed and poured into the container 310 (e.g., a glass beaker). The stirring magneton 350 was placed into the container 310. Two ends of the Nd:YAG crystal rod were wrapped with a preset thickness of a sealing tape and were inserted into second holes 332 of two parallel supporting plates 330 (e.g., glass plates), respectively. In the embodiment, a value of the preset thickness is not limiting, as long as the Nd:YAG rod can be fixed in the second holes 332. Both ends of each of the two rectangular supporting rods 320 were inserted into two first holes 331 of the two parallel supporting plates 330. The two rectangular supporting rods 320 were placed on the opening of the container 310 to allow the Nd:YAG crystal rod to be completely immersed into the mixed acidic solution in the container 310. The container 310 was placed on a heating magnetic stirrer. A magnetic stirring rate was 250 rpm, a heating temperature was 250° C., and a heating stirring time was 6 hours. A dissolved Nd:YAG crystal rod was removed and an Nd:YAG single crystal fiber core shown in FIG. 6A was prepared by rinsing the dissolved Nd:YAG crystal rod with ethanol. The Nd:YAG single crystal fiber core had a diameter of 111.5 μm and a length of 2.5 cm.

A polishing liquid with 5% mass fraction of corundum was prepared. A pH value of the polishing liquid was adjusted to 3 using a hydrochloric acid solution with a solute mass fraction of 37%. The Nd:YAG single crystal fiber core was immersed in a container (e.g., the container 310) containing the polishing liquid by using a clamp and a central axis of the Nd:YAG single crystal fiber core was made to coincide with a central axis of the container. The container was placed on a magnetic stirrer and the stirring magneton 350 was rotated in the container to drive the polishing liquid to rotate to polish the Nd:YAG single crystal fiber core. The magnetic stirring rate was 300 rpm and the polishing time was 24 hours. After the Nd:YAG single crystal fiber core was polished, the Nd:YAG single crystal fiber core was cleaned for 1 minute by an ultrasonic cleaning machine to remove the polishing liquid adhered on a surface of the Nd:YAG single crystal fiber core. The polished Nd:YAG single crystal fiber core shown in FIG. 6B was prepared. A diameter of the Nd:YAG single crystal fiber core was 101.1 μm. Compared with a non-polished Nd:YAG single crystal fiber core (shown in FIG. 6A), the polished Nd:YAG single crystal fiber core had a higher surface smoothness and a lower surface roughness.

FIG. 7 is a schematic diagram illustrating an exemplary bending performance test of a polished Nd:YAG single crystal fiber core according to some embodiments of the present disclosure. As shown in FIG. 7, line 710 represents the polished Nd:YAG single crystal fiber core and rod 720 represents a stainless steel rod. According to FIG. 7, the Nd:YAG single crystal fiber core 710 prepared in the embodiment has an excellent bending performance.

FIGS. 6A, 6B, and 7 were obtained by performing an enlarging capture by an automatic image measuring instrument VMS-3020E.

Further, raw materials required for growing the YAG single crystal fiber cladding was calculated as including: 2.85 g Y₂O₃ and 2.14 g Al₂O₃. The above raw materials were placed into the dissolution zone 412 of the growth chamber 410 (e.g., a silver inner liner) having a diameter of 20 mm and a height of 150 mm. The baffle 415 (e.g., a silver baffle) with an aperture ratio of 9% was placed into the growth chamber 410. A K₂CO₃ solution with 2 mol/L was poured into the growth chamber 410 and a volume of the K₂CO₃ solution was 65% of a volume of the growth chamber 410. The Nd:YAG single crystal fiber core was fixed to the supporting assembly 417 (e.g., a silver wire frame) by the fixing assembly 416 (e.g., a silver wire). The supporting assembly 417 (e.g., a silver wire frame) fixed with the Nd:YAG single crystal fiber core was put into the growth chamber 410 to cause the Nd:YAG single crystal fiber core to locate in the growth zone 411 and to be immersed by the K₂CO₃ solution.

The growth chamber 410 was sealed by welding and the sealed growth chamber 410 was loaded into the safety device 420. In order to balance pressures inside and outside the growth chamber 410 to protect the growth chamber 410, deionized water was filled in a gap between the growth chamber 410 and the safety device 420 and a volume of the deionized water was 70% of a volume of the gap.

The safety device 420 was sealed using a metal ring cone and the sealed safety device 420 was placed into the two-stage heating device 430 (e.g., a two-stage independent heating resistance furnace). The thermal insulation layer 433 (e.g., a light high-alumina brick) was disposed between the first heating device 431 and the second heating device 432. A heating temperature of the second heating device 432 was set as 635° C. and a heating temperature of the first heating device 431 was set as 610° C. Pressures in both the safety device 420 and the growth chamber 410 were 140 MPa and a reaction time was 20 days. After the reaction was completed, a temperature of the two-stage heating device 430 was cooled to the room temperature and a Nd:YAG single crystal fiber was obtained. The Nd:YAG single crystal fiber was rinsed using the deionized water to remove the raw material residue adhered on a surface of the Nd:YAG single crystal fiber. The prepared Nd:YAG single crystal fiber had a smooth surface and a uniform diameter. A thickness of the YAG single crystal fiber cladding was 420 μm.

### Embodiment 2

A doped concentration of Nd was set as 0.01, and raw materials required for generating an Nd:YAG crystal ingot were calculated as including: 42.4 g Nd₂O₃, 2816.8 g Y₂O₃, and 2141.2 g Al₂O₃. A purity of each of the raw materials was greater than or equal to 99.99%. After the raw materials were mixed, the mixed raw material was poured into a mold and pressed into a block under a pressure of 140 MPa. The block was calcined at 1300° C. for 12 hours, and an Nd:YAG block was prepared. The Nd:YAG block was placed into an iridium-gold crucible in a single crystal furnace. A YAG single crystal with a [111] orientation was used as a seed crystal. A Nd:YAG crystal ingot was prepared after single crystal furnace charging operation, vacuum pumping operation, nitrogen introducing operation, material melting operation, seed crystal preheating operation, seed crystal introducing operation, temperature adjustment operation, necking operation, shoulder release operation, equal diameter growth operation, ending operation, cooling operation, crystal extraction operation, etc. A flowing rate of flowing nitrogen was 3 mL/min. During the growth of the Nd:YAG crystal ingot, a rotational speed of the seed crystal was 15 rpm, a lifting speed of the seed crystal was 0.6 mm/h, a growth temperature was 2000° C., and a growth time was 15 days.

An Nd:YAG crystal rod shown in FIG. 5 was prepared by performing a cutting operation, a grinding operation, and a polishing operation on the Nd:YAG crystal ingot. The Nd:YAG crystal rod had a diameter of 1.7 mm and a length of 3 cm.

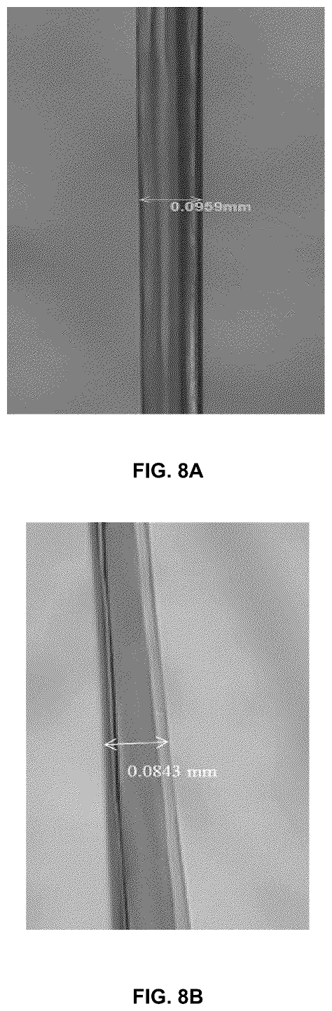

150 mL of a concentrated sulfuric acid solution with a mass fraction of 70% and 150 mL of a concentrated phosphoric acid solution with a mass fraction of 88% were mixed and poured into the container 310 (e.g., a glass beaker). The stirring magneton 350 was placed into the container 310. (e.g., a glass plate). Two ends of the Nd:YAG crystal rod were wrapped with a preset thickness of a sealing tape and were inserted into second holes 332 of two parallel supporting plates 330 (e.g., glass plates), respectively. In the embodiment, a value of the preset thickness is not limiting, as long as the Nd:YAG rod can be fixed in the second holes 332. Both ends of each of the two rectangular supporting rods 320 were inserted into two first holes 331 of the two parallel supporting plates 330. The two rectangular supporting rods 320 were placed on the opening of the container 310 to allow the Nd:YAG crystal rod to be completely immersed into the mixed acidic solution in the container 310. The container 310 was placed on a heating magnetic stirrer. A magnetic stirring rate was 250 rpm, a heating temperature was 300° C., and a heating stirring time was 7 hours. A dissolved Nd:YAG crystal rod was removed and an Nd:YAG single crystal fiber core shown in FIG. 8A was prepared by rinsing the dissolved Nd:YAG crystal rod with ethanol. The Nd:YAG single crystal fiber core had a diameter of 95.9 μm and a length of 2.5 cm.

A polishing liquid with 5% mass fraction of corundum was prepared. A pH value of the polishing liquid was adjusted to 4 using a hydrochloric acid solution with a solute mass fraction of 37%. The Nd:YAG single crystal fiber core was immersed in a container (e.g., the container 310) containing the polishing liquid by using a clamp and a central axis of the Nd:YAG single crystal fiber core was made to coincide with a central axis of the container. The container was placed on a magnetic stirrer and the stirring magneton 350 was rotated in the container to drive the polishing liquid to rotate to polish the Nd:YAG single crystal fiber core. The magnetic stirring rate was 500 rpm, and the polishing time was 40 hours. After the Nd:YAG single crystal fiber core was polished, the Nd:YAG single crystal fiber core was cleaned for 1 minute by an ultrasonic cleaning machine to remove the polishing liquid adhered on a surface of the Nd:YAG single crystal fiber core. The polished Nd:YAG single crystal fiber core shown in FIG. 8B was prepared. A diameter of the Nd:YAG single crystal fiber core was 84.3 μm. Compared with a non-polished Nd:YAG single crystal fiber core (shown in FIG. 8A), the polished Nd:YAG single crystal fiber core had a higher surface smoothness and a lower surface roughness.

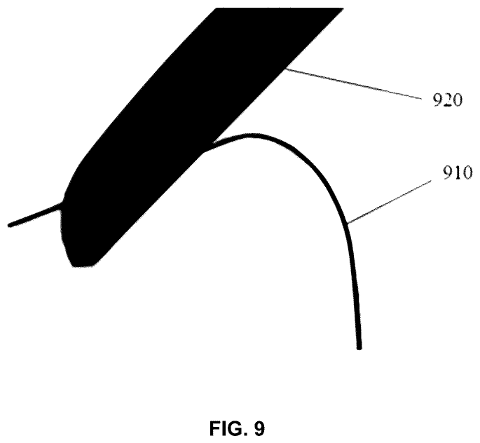

FIG. 9 is a schematic diagram illustrating an exemplary bending performance test of a polished Nd:YAG single crystal fiber core according to some embodiments of the present disclosure. As shown in FIG. 9, line 910 represents the polished Nd:YAG single crystal fiber core and rod 920 represents a stainless steel rod. According to FIG. 9, the Nd:YAG single crystal fiber core 910 prepared in the embodiment has an excellent bending performance.

FIGS. 8A, 8B, and 9 were obtained by performing an enlarging capture by an automatic image measuring instrument VMS-3020E.

Further, raw materials required for growing the YAG single crystal fiber cladding was calculated as including: 2.85 g Y₂O₃ and 2.14 g Al₂O₃. The above raw materials were placed into the dissolution zone 412 of the growth chamber 410 (e.g., a silver inner liner) having a diameter of 20 mm and a height of 150 mm. The baffle 415 (e.g., a silver baffle) with an aperture ratio of 7% was placed into the growth chamber 410. A K₂CO₃ solution with 1.5 mol/L was poured into the growth chamber 410 and a volume of the K₂CO₃ solution accounted was 75% of a volume of the growth chamber 410. The Nd:YAG single crystal fiber core was fixed to the supporting assembly 417 (e.g., a silver wire frame) by the fixing assembly 416 (e.g., a silver wire). The supporting assembly 417 (e.g., a silver wire frame) fixed with the Nd:YAG single crystal fiber core was put into the growth chamber 410 to cause the Nd:YAG single crystal fiber core to locate in the growth zone 411 and to be immersed by the K₂CO₃ solution.

The growth chamber 410 was sealed by welding and the sealed growth chamber 410 was loaded into the safety device 420. In order to balance pressures inside and outside the growth chamber 410 to protect the growth chamber 410, deionized water was filled in a gap between the growth chamber 410 and the safety device 420 and a volume of the deionized water was 70% of a volume of the gap.

The safety device 420 was sealed and the sealed safety device 420 was placed into the two-stage heating device 430 (e.g., a two-stage independent heating resistance furnace). The thermal insulation layer 433 (e.g., a light high-alumina brick) was disposed between the first heating device 431 and the second heating device 432. A heating temperature of the second heating device 432 was set as 650° C., and a heating temperature of the first heating device 431 was set as 630° C. Pressures in both the safety device 420 and the growth chamber 410 were 160 MPa and a reaction time was 18 days. After the reaction was completed, a temperature of the two-stage heating device 430 was cooled to the room temperature and a Nd:YAG single crystal fiber was obtained. The Nd:YAG single crystal fiber was rinsed using the deionized water to remove the raw material residue adhered on a surface of the Nd:YAG single crystal fiber. The prepared Nd:YAG single crystal fiber had a smooth surface and a uniform diameter. A thickness of the YAG single crystal fiber cladding was 350 μm.

Some embodiments of the present disclosure provide methods and devices for preparing crystal cladding (e.g., single crystal cladding or polycrystal cladding), for example, YAG crystal cladding, YₓAl₍₁₋ₓ₎O₃ crystal cladding. Al₂O₃ crystal cladding and the doped crystal cladding thereof. For the convenience of description, the YAG crystal cladding will be described as an example below.

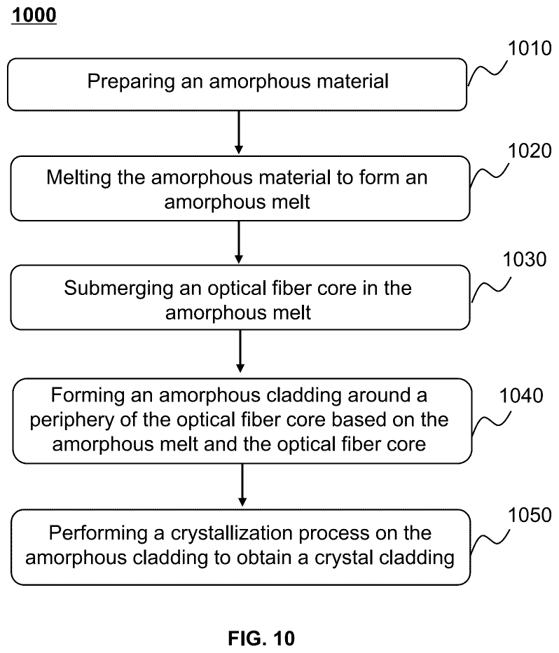

FIG. 10 is a flowchart illustrating an exemplary process for preparing a crystal cladding according to some embodiments of the present disclosure. In some embodiments, process 1000 may be performed by one or more components in a crystal cladding preparation device (e.g., a device 1100 for preparing a crystal cladding). In some embodiments, process 1000 may be automatically executed by a control system. For example, process 1000 may be realized via a control instruction, and the control system controls various components to complete various operations of process 1000 based on the control instruction. In some embodiments, process 1000 may be executed semi-automatically. For example, one or more operations of process 1000 may be manually performed by an operator. In some embodiments, one or more additional operations not described may be added to process 1000, and/or one or more operations discussed herein may be deleted from process 1000. Additionally, the order of operations shown in FIG. 10 is not limiting. As shown in FIG. 10, process 1000 may include the following operations 1010-1050.

In 1010, an amorphous material may be prepared. In some embodiments, operation 1010 may be performed by an amorphous material preparation component 1110.

In some embodiments, an amorphous phase material may include a substance in which internal microscopic material units (e.g., atoms, molecules, etc.) are arranged without long-range order characteristics, or are arranged disorderly and lack periodicity. In some embodiments, a crystalline phase material may include a substance in which internal microscopic material units (e.g., atoms, molecules, etc.) are arranged in an orderly manner according to certain rules. In some embodiments, a crystalline phase material and an amorphous phase material may convert into each other under certain preset conditions.

In some embodiments, a crystalline phase material may be converted into an amorphous phase material in a variety of ways. In some embodiments, an amorphous phase material may be formed by melting a crystalline phase material and adjusting the parameters (for example, temperature, pressure, pH value, etc.) of the melted crystalline phase material. In some embodiments, an amorphous phase material may be formed by applying mechanical force to a crystalline phase material, which may make the crystalline phase material subjected to repeated deformation, fracture, and recombination. In some embodiments, an amorphous phase material may be formed by injecting impurity atoms into a crystalline phase material through the ion implantation technology to destroy the crystal structure of the crystalline phase material. In some embodiments, an amorphous phase material may be formed by high-energy radiation which may be used to destroy the long-range order of a crystalline material.

In some embodiments, the amorphous material preparation component may melt a raw material used to prepare the amorphous material to form a raw material melt, and perform a cooling process on the raw material melt to prepare the amorphous material. In some embodiments, a melting process of the raw material may be accomplished by a melt assembly (e.g., a melt assembly 1111). In some embodiments, the cooling process may be implemented by a cooling assembly (e.g., a dispersing and cooling assembly 1112). The following description takes the amorphous material being an amorphous YAG (Yttrium Aluminum Garnet, Y₃Al₅O₁₂) as an example.

In some embodiments, the raw material may be in the form of a powder, a block, a pellet, or the like.

In some embodiments, a purity of the raw material may be within a predetermined range to balance costs and a performance of a subsequently grown crystal cladding. In some embodiments, the purity of the raw material may be greater than or equal to 99.0%. In some embodiments, the purity of the raw material may be greater than or equal to 99.9%. In some embodiments, the purity of the raw material may be greater than or equal to 99.99%. In some embodiments, the purity of the raw material may be greater than or equal to 99.999%.

In some embodiments, components of the raw material and the amorphous material may be the same or different.

In some embodiments, the raw material may include yttrium-containing oxides and aluminum-containing oxides. In some embodiments, the yttrium-containing oxides may include but are not limited to Y₂O₃, or the like. In some embodiments, the aluminum-containing oxides may include but are not limited to Al₂O₃, or the like. In some embodiments, during a melting process of the yttrium-containing oxides and the aluminum-containing oxides, the yttrium-containing oxides and the aluminum-containing oxides may undergo a chemical reaction (e.g., a solid-phase reaction) to generate a YAG melt. Correspondingly, the raw material melt is the YAG melt.

In some embodiments, the raw material may include a crystalline-phase YAG solid (e.g., a YAG polycrystalline powder). In some embodiments, the crystalline-phase YAG solid may be melted to form the YAG melt. Correspondingly, the raw material melt is the YAG melt. In contrast to a way of generating the YAG melt based on a reaction of an oxide material, a way of obtaining the YAG melt based on the crystalline-phase YAG solid avoids components of the oxide material (e.g., the yttrium-containing oxides and the aluminum-containing oxides) from volatilization or segregation during melting at a high temperature, which ensures accuracy of a subsequent process.

In some embodiments, the crystalline-phase YAG solid may be prepared using a solid-phase reaction technique. In some embodiments, materials (e.g., the yttrium-containing oxides and the aluminum-containing oxides) for preparing the crystalline-phase YAG solid may be mixed in a predetermined ratio and then calcined under a predetermined condition to produce the crystalline-phase YAG solid. In some embodiments, the predetermined condition may include a predetermined calcination temperature and a predetermined calcination time.

In some embodiments, the predetermined calcination temperature may be controlled to be within a predetermined range to improve a purity and quality of the crystalline-phase YAG solid. In some embodiments, the predetermined calcination temperature may be in a range of 1400° C. to 1700° C. In some embodiments, the predetermined calcination temperature may be in a range of 1420° C. to 1680° C. In some embodiments, the predetermined calcination temperature may be in a range of 1440° C. to 1660° C. In some embodiments, the predetermined calcination temperature may be in a range of 1460° C. to 1640° C. In some embodiments, the predetermined calcination temperature may be in a range of 1480° C. to 1620° C. In some embodiments, the predetermined calcination temperature may be in a range of 1500° C. to 1600° C. In some embodiments, the predetermined calcination temperature may be in a range of 1520° C. to 1580° C. In some embodiments, the predetermined calcination temperature may be in a range of 1540° C. to 1560° C.

In some embodiments, the predetermined calcination time may be controlled within a predetermined range to improve calcination efficiency and to ensure the quality of the crystalline-phase YAG solid. In some embodiments, the predetermined calcination time may be in a range of 5 h to 25 h. In some embodiments, the predetermined calcination time may be in a range of 6 h to 24 h. In some embodiments, the predetermined calcination time may be in a range of 7 h to 23 h. In some embodiments, the predetermined calcination time may be in a range of 8 h to 22 h. In some embodiments, the predetermined calcination time may be in a range of 9 h to 21 h. In some embodiments, the predetermined calcination time may be in a range of 10 h to 20 h. In some embodiments, the predetermined calcination time may be in a range of 10.5 h to 19.5 h. In some embodiments, the predetermined calcination time may be in a range of 11 h to 19 h. In some embodiments, the predetermined calcination time may be in a range of 11.5 h to 18.5 h. In some embodiments, the predetermined calcination time may be in a range of 12 h to 18 h. In some embodiments, the predetermined calcination time may be in a range of 12.5 h to 17.5 h. In some embodiments, the predetermined calcination time may be in a range of 13 h to 17 h. In some embodiments, the predetermined calcination time may be in a range of 13.5 h to 16.5 h. In some embodiments, the predetermined calcination time may be in a range of 14 h to 16 h. In some embodiments, the predetermined calcination time may be in a range of 14.5 h to 15.5 h.

In some embodiments, the crystalline-phase YAG solid may be prepared using a chemical co-precipitation technique. In some embodiments, a solution of metal salts comprising yttrium and aluminum may be mixed with a precipitating agent (e.g., an alkaline solution) to obtain a solution comprising a precursor. Further, filtration, drying, and calcination operations may be performed on the solution comprising the precursor to obtain the crystalline-phase YAG solid. In some embodiments, oxides corresponding to yttrium and aluminum (e.g., yttrium oxide and aluminum oxide) may be dissolved in an acid solution (e.g., hydrochloric acid, sulfuric acid, nitric acid) to obtain a corresponding solution of metal salts. Correspondingly, the solution of metal salts comprising yttrium and aluminum may include aluminum nitrate and yttrium nitrate, aluminum chloride, yttrium chloride, or the like. In some embodiments, the precipitating agent may include at least one of ammonia or ammonium bicarbonate.

In some embodiments, the crystalline-phase YAG solid may also be obtained using other techniques such as a sol-gel technique, a solvent (e.g., water) thermal technique, or the like.

In some embodiments, melting-related parameter(s) may be determined based on properties of the raw material. In some embodiments, the melting-related parameter(s) may be determined by a controlling component 1150. Setting corresponding melting-related parameter(s) for different raw materials may realize automatic control of the melting process of the raw materials.

In some embodiments, the properties of the raw material may include, but are not limited to, a state of the raw material (e.g., a powder, a block, a pellet), components, a purity, or the like.

In some embodiments, the melting-related parameter(s) may include but are not limited to, a heating rate, a melting temperature, an insulting time, or the like.

In some embodiments, the heating rate may be controlled within a predetermined range to improve the melting efficiency of the raw material and to ensure the quality of the raw material melt. In some embodiments, the heating rate may be in a range of 1° C./min to 12° C./min. In some embodiments, the heating rate may be in a range of 1.5° C./min to 11.5° C./min. In some embodiments, the heating rate may be in a range of 2° C./min to 11° C./min. In some embodiments, the heating rate may be in a range of 2.5° C./min to 10.5° C./min. In some embodiments, the heating rate may be in a range of 3° C./min to 10° C./min. In some embodiments, the heating rate may be in a range of 3.5° C./min to 9.5° C./min. In some embodiments, the heating rate may be in a range of 4° C./min to 9° C./min. In some embodiments, the heating rate may be in a range of 4.5° C./min to 8.5° C./min. In some embodiments, the heating rate may be in a range of 5° C./min to 8° C./min. In some embodiments, the heating rate may be in a range of 5.5° C./min to 7.5° C./min. In some embodiments, the heating rate may be in a range of 6° C./min to 7° C./min.

In some embodiments, the melting temperature may be controlled within a predetermined range to make the raw material react or melt sufficiently (e.g., the yttrium-containing oxides and the aluminum-containing oxides reacting chemically to prepare the YAG melt, or the crystalline-phase YAG solid melting to form the YAG melt), thereby ensuring the quality of the raw material melt. In some embodiments, the melting temperature may be in a range of 1900° C.-2100° C. In some embodiments, the melting temperature may be in a range of 1910° C. to 2090° C. In some embodiments, the melting temperature may be in a range of 1920° C. to 2080° C. In some embodiments, the melting temperature may be in a range of 1930° C. to 2070° C. In some embodiments, the melting temperature may be in a range of 1940° C. to 2060° C. In some embodiments, the melting temperature may be in a range of 1950° C. to 2050° C. In some embodiments, the melting temperature may be in a range of 1960° C. to 2040° C. In some embodiments, the melting temperature may be in a range of 1970° C. to 2030° C. In some embodiments, the melting temperature may be in a range of 1980° C. to 2020° C. In some embodiments, the melting temperature may be in a range of 1990° C. to 2010° C.

In some embodiments, the insulting time needs to be controlled within a predetermined range to allow the raw material to react or melt sufficiently to ensure the quality of the raw material melt. In some embodiments, the insulting time may be in a range of 2 h to 12 h. In some embodiments, the insulting time may be in a range of 3 h to 11 h. In some embodiments, the insulting time may be in a range of 3.5 h to 10.5 h. In some embodiments, the insulting time may be in a range of 4 h to 10 h. In some embodiments, the insulting time may be in a range of 4.5 h to 9.5 h. In some embodiments, the insulting time may be in a range of 5 h to 9 h. In some embodiments, the insulting time may be in a range of 5.5 h to 8.5 h. In some embodiments, the insulting time may be in a range of 6 h to 8 h. In some embodiments, the insulting time may be in a range of 6.5 h to 7.5 h.

In some embodiments, as described above, after obtaining the raw material melt, a cooling process may be performed on the raw material melt to prepare the amorphous material. In some embodiments, the cooling process may be performed on the raw material melt to form the amorphous material by ejecting a fluid. By ejecting the fluid, the raw material melt may be dispersed into fine melt droplets, and accordingly, a contact area between the raw material melt and the fluid or air may be increased, so that the raw material melt can be cooled down rapidly, thereby improving a preparing efficiency and quality of the amorphous material.

In some embodiments, the controlling component may determine parameter(s) of the cooling process based on properties of the raw material melt. In some embodiments, the parameter(s) of the cooling process may be determined by the controlling component 1150. Setting corresponding parameter(s) of the cooling process for different raw material melts can make the preparation process of the amorphous material adaptive and ensure that amorphous materials of higher quality can be prepared in different scenarios.

In some embodiments, the properties of the raw material melt may include but are not limited to, a type, a temperature, a viscosity, etc., of the raw material melt.

In some embodiments, the parameter(s) of the cooling process may include but are not limited to, a cooling rate, a temperature range for cooling, a pressure during the cooling process, or the like. In some embodiments, the parameter(s) of the cooling process may include but are not limited to, properties of the fluid, an ejection angle, an ejection pressure, a distance between an ejection port and the raw material melt, or the like.

In some embodiments, the properties of the fluid may include a type, a state, a thermal conductivity, etc., of the fluid. In some embodiments, the type of the fluid may include but is not limited to, N₂, CO₂, air, inert gas, or the like. In some embodiments, the state of the fluid may include a gaseous state or a liquid state. For example, N₂ refers to nitrogen gas or liquid nitrogen. In the process of ejecting the liquid nitrogen or dispersing the raw material melt, the liquid nitrogen may vaporize and absorb heat of the raw material melt, so that the raw material melt can be cooled down more rapidly, which improves the efficiency of an amorphous processing and ensures the quality of the amorphous material.

In some embodiments, the ejection angle refers to an angle between an ejection direction of the fluid and a horizontal plane. In some embodiments, the ejection angle may be controlled within a predetermined range to rapidly cool the raw material melt to obtain a high-quality amorphous material. In some embodiments, the ejection angle may be in a range of 20° to 70°. In some embodiments, the ejection angle may be in a range of 25° to 65°. In some embodiments, the ejection angle may be in a range of 30° to 60°. In some embodiments, the ejection angle may be in a range of 35° to 55°. In some embodiments, the ejection angle may be in a range of 40° to 50°.

In some embodiments, the ejection pressure refers to a force applied to the fluid. In some embodiments, to ensure thorough dispersion of the raw material melt for rapid cooling and to obtain the high-quality amorphous material, the ejection pressure may be controlled within a predetermined range. In some embodiments, the ejection pressure may be in a range of 0.1 MPa to 2.5 MPa. In some embodiments, the ejection pressure may be in a range of 0.2 MPa to 2.2 MPa. In some embodiments, the ejection pressure may be in a range of 0.4 MPa to 2 MPa. In some embodiments, the ejection pressure may be in a range of 0.6 MPa to 1.8 MPa. In some embodiments, the ejection pressure may be in a range of 0.8 MPa to 1.6 MPa. In some embodiments, the ejection pressure may be in a range of 1 MPa to 1.4 MPa. In some embodiments, the ejection pressure may be in a range of 1.1 MPa to 1.3 MPa.

In some embodiments, to ensure thorough dispersion of the raw material melt for rapid cooling and to obtain the high-quality amorphous material, the distance between the ejection port and the raw material melt may be controlled to be within a predetermined range. In some embodiments, the distance between the ejection port and the raw material melt may be in a range of 3 cm to 12 cm. In some embodiments, the distance between the ejection port and the raw material melt may be in a range of 4 cm to 11 cm. In some embodiments, the distance between the ejection port and the raw material melt may be in a range of 5 cm to 10 cm. In some embodiments, the distance between the ejection port and the raw material melt may be in a range of 6 cm to 9 cm. In some embodiments, the distance between the ejection port and the raw material melt may be in a range of 7 cm to 8 cm.

In some embodiments, parameter(s) for preparing the amorphous material (e.g., including the melting-related parameter(s) and/or the parameter(s) of the cooling process) may be determined by a machine learning model. In some embodiments, the controlling component 1150 and/or other processing devices may train the machine learning model based on properties of a historical raw material, properties of a historical raw material melt, parameter(s) for preparing a historical amorphous material (e.g., historical melting-related parameter(s) and historical parameter(s) of the cooling process), or the like. For example, an input of the machine learning model may include the properties of the raw material, and an output of the machine learning model may include the melting-related parameter(s). As another example, the input of the machine learning model may include the properties of the raw material melt, and the output of the machine learning model may include the parameter(s) of the cooling process. As yet another example, the input of the machine learning model may include the properties of the material, and the output of the machine learning model may include the parameter(s) for preparing the amorphous material.

In some embodiments, the input of the machine learning model may also include an environmental condition (e.g., humidity and temperature).

In some embodiments, the parameter(s) of the machine learning model may be dynamically updated based on updated experimental data, thereby enhancing the comprehensive learning capability of the machine learning model to determine more accurate parameter(s) for preparing the amorphous material.

In some embodiments, the controlling component 1150 may determine the parameter(s) for preparing the amorphous material (e.g., the melting-related parameter(s) and the parameter(s) of the cooling process) based on the properties of the raw material and/or the properties of the raw material melt, and a trained machine learning model. In some embodiments, the controlling component 1150 may also adaptively adjust the parameter(s) for preparing the amorphous material output by the machine learning model based on actual situation(s) (e.g., the environmental condition) to adapt to different actual situations.

In some embodiments, the parameter(s) for preparing the amorphous material may also be determined in other manners. For example, the parameter(s) may be determined based on statistical data, empirical parameter(s), user customization, or the like.

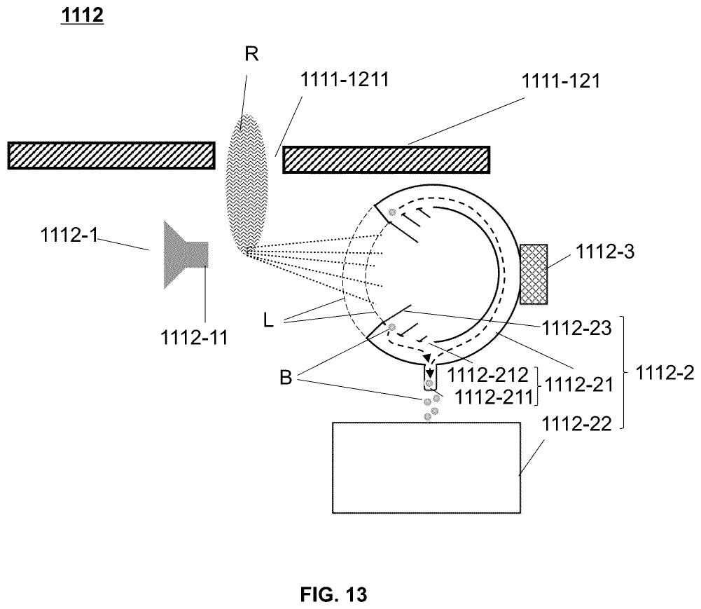

In some embodiments, as described above, the dispersed fine melt droplets subjected to the rapid cooling process may form the amorphous material (fine amorphous melts and/or amorphous solid particles). In some embodiments, after preparing the amorphous material, the amorphous material may be collected. In some embodiments, during a collection process, an oscillating element may oscillate the amorphous material to avoid the fine amorphous melts and/or the amorphous solid particles from adhering to an inner wall of the cooling assembly (e.g., the dispersing and cooling assembly 1112), thereby improving a utilization rate of the material. More description regarding the oscillation process may be found in FIG. 13 and the descriptions thereof.

In 1020, the amorphous material may be melted to form the amorphous melt. In some embodiments, operation 1020 may be performed by an amorphous cladding preparation component 1120.

In some embodiments, a melting temperature interval for melting the amorphous material (e.g., an amorphous YAG solid particle) to form the amorphous melt may be lower than a melting temperature of a crystalline-phase material (e.g., a YAG single-crystal fiber core). During the melting process of the amorphous phase material, if the temperature is not properly controlled, for example, the actual melting temperature is higher than the melting temperature of the amorphous phase material, or reaches the melting temperature of the crystalline phase material, the amorphous phase material will crystallize and convert into the crystal phase material.

The following description takes the amorphous material being an amorphous YAG (Yttrium Aluminum Garnet, Y₃Aₗ₅O₁₂) as an example.

In some embodiments, to prevent crystallization of the amorphous material during the melting process, and at the same time to ensure that the amorphous material melts to form the amorphous melt, a melting temperature interval of the amorphous material may be controlled to be in a predetermined range. In some embodiments, the melting temperature interval of the amorphous material may be in a range of 1500° C. to 1800° C. In some embodiments, the melting temperature interval of the amorphous material may be in a range of 1520° C. to 1780° C. In some embodiments, the melting temperature interval of the amorphous material may be in a range of 1540° C. to 1760° C. In some embodiments, the melting temperature interval of the amorphous material may be in a range of 1560° C. to 1740° C. In some embodiments, the melting temperature interval of the amorphous material may be in a range of 1580° C. to 1720° C. In some embodiments, the melting temperature interval of the amorphous material may be in a range of 1600° C. to 1700° C. In some embodiments, the melting temperature interval of the amorphous material may be in a range of 1620° C. to 1680° C. In some embodiments, the melting temperature interval of the amorphous material may be in a range of 1640° C. to 1660° C.

In some embodiments, to sufficiently melt the amorphous material to form the amorphous melt, it may be necessary to maintain the melting temperature of the amorphous material for a predetermined insulting time, and the predetermined insulting time may be controlled to be in a predetermined range. In some embodiments, the predetermined insulting time may be in a range of 2 h to 15 h. In some embodiments, the predetermined insulting time may be in a range of 3 h to 13 h. In some embodiments, the predetermined insulting time may be in a range of 4 h to 11 h. In some embodiments, the predetermined insulting time may be in a range of 5 h to 10 h. In some embodiments, the predetermined insulting time may be in a range of 6 h to 9 h. In some embodiments, the predetermined insulting time may be in a range of 7 h to 8 h.

In 1030, an optical fiber core may be submerged in the amorphous melt. In some embodiments, operation 1030 may be performed by the amorphous cladding preparation component 1120.

In some embodiments, the optical fiber core may be pre-prepared. In some embodiments, a crystal rod may be prepared first, and then the optical fiber core may be obtained by dissolving and refining the crystal rod in an acid solution, grinding the crystal rod, polishing the crystal rod, or the like. The method of preparing the optical fiber core may refer to the descriptions in other parts of this specification (for example, FIG. 1 and its related descriptions), and will not be described again here. In some embodiments, the optical fiber core may be a single-crystal optical fiber core. In the disclosure, the optical fiber core and the fiber core can be exchanged and express the same meaning.

In some embodiments, the optical fiber core may be a doped or non-doped optical fiber core. Taking a YAG single-crystal fiber core as an example, the optical fiber core may be a doped or non-doped YAG single-crystal fiber core. In some embodiments, a dopant element (e.g., a rare earth element) in the doped YAG may occupy Y³⁺ in the YAG in a substitutional doping manner. In some embodiments, a molecular formula of the doped YAG may be expressed as X₃ₓY₃₍ₓ₋₁₎Aₗ₅O₁₂, wherein X denotes the dopant element (e.g., at least one of Nd, Pr, Cr, Tb, Ho, Tm, or Yb), and x denotes a doping concentration of the dopant element. In some embodiments, the doping concentration of the dopant element may be determined based on practical need(s).

In some embodiments, the amorphous cladding preparation component (e.g., a clamping assembly) may submerge the optical fiber core horizontally in the amorphous melt. By submerging the optical fiber core horizontally, the amorphous melt around a periphery of the optical fiber core may be avoided from slipping under gravity (which may result in a non-uniform thickness of a subsequently prepared amorphous cladding). In the present disclosure, “submerging horizontally” refers to that an angle between the optical fiber core and the horizontal plane is less than a predetermined threshold. In some embodiments, the predetermined threshold may be in a range of 0° to 15°. In some embodiments, the predetermined threshold may be in a range of 2° to 13°. In some embodiments, the predetermined threshold may be in a range of 4° to 11°. In some embodiments, the predetermined threshold may be in a range of 6° to 9°. In some embodiments, the predetermined threshold may be in a range of 7° to 8°. In some embodiments, the predetermined threshold may be in a range of 0° to 5°. In some embodiments, the predetermined threshold may be in a range of 1° to 4°. In some embodiments, the predetermined threshold may be in a range of 2° to 3°.

In some embodiments, the optical fiber core may also be submerged in the amorphous melt in other manners, e.g., vertically submerging, tiltedly submerging, etc., if there is no need to consider a thickness of the cladding or a thickness requirement is not high.

In 1040, an amorphous cladding may be formed around the periphery of the optical fiber core based on the amorphous melt and the optical fiber core. In some embodiments, operation 1040 may be performed by the amorphous cladding preparation component 1120.

In some embodiments, as mentioned above, since the melting temperature interval for melting the amorphous material (e.g., the amorphous YAG solid particle) to form the amorphous melt (e.g., the amorphous YAG melt) is lower than a melting temperature of the crystalline-phase material (e.g., the YAG single-crystal fiber core), the crystalline-phase material (e.g., the YAG single crystal fiber core) submerged in the amorphous melt (e.g., the amorphous YAG melt) is not corroded.

Since the amorphous melt has a certain viscosity, correspondingly, in some embodiments, the amorphous cladding around the periphery of the optical fiber core may be formed by adhering the amorphous melt at a constant temperature (e.g., a specific temperature within the melting temperature interval for melting the amorphous material to form the amorphous melt).

In some embodiments, the constant temperature may include a constant temperature value. In some embodiments, the constant temperature value may include a specific temperature value within the melting temperature interval for melting the amorphous material to form the amorphous melt. Taking the amorphous YAG melt as an example, the specific temperature value may be a specific temperature value in a range of 1500° C.-1800° C. For example, the specific temperature value may be 1500° C., 1550° C., 1600° C., 1650° C., 1700° C., 1750° C., 1800° C., or the like.

In some embodiments, the constant temperature may include a constant temperature range. In some embodiments, the constant temperature range may include a specific temperature interval within the melting temperature interval for melting the amorphous material to form the amorphous melt. Taking the amorphous YAG melt as an example, the specific temperature interval may be a specific temperature interval in a range of 1500° C. to 1800° C. For example, the specific temperature interval may be a temperature interval in a range of 1500° C. to 1550° C., 1550° C. to 1600° C., 1600° C. to 1650° C., 1650° C. to 1700° C., 1700° C. to 1750° C., 1750° C. to 1800° C., or the like.

As the viscosity of the amorphous melt varies with temperature, accordingly, in some embodiments, the controlling component may adjust the viscosity of the amorphous melt by adjusting the temperature to further adjust the thickness of the amorphous cladding.

In some embodiments, the amorphous melt around the periphery of the optical fiber core may be crystallized by cooling during a predetermined cooling interval to grow the amorphous cladding.

In some embodiments, the predetermined cooling interval may be controlled within a predetermined range to ensure the quality of the amorphous cladding. In some embodiments, the predetermined cooling interval may be in a range of 10° C. to 60° C. In some embodiments, the predetermined cooling interval may be in a range of 15° C. to 55° C. In some embodiments, the predetermined cooling interval may be in a range of 20° C. to 50° C. In some embodiments, the predetermined cooling interval may be in a range of 22° C. to 48° C. In some embodiments, the predetermined cooling interval may be in a range of 24° C. to 46° C. In some embodiments, the predetermined cooling interval may be in a range of 26° C. to 44° C. In some embodiments, the predetermined cooling interval may be in a range of 28° C. to 42° C. In some embodiments, the predetermined cooling interval may be in a range of 30° C. to 40° C. In some embodiments, the predetermined cooling interval may be in a range of 32° C. to 38° C. In some embodiments, the predetermined cooling interval may be in a range of 34° C. to 36° C.

In some embodiments, a cooling rate may be controlled within a predetermined range to make the thickness of the amorphous cladding uniform and to ensure the quality of the amorphous cladding. In some embodiments, the cooling rate may be in a range of 0.2° C./h to 8° C./h. In some embodiments, the cooling rate may be in a range of 0.3° C./h to 7° C./h. In some embodiments, the cooling rate may be in a range of 0.4° C./h to 6° C./h. In some embodiments, the cooling rate may be in a range of 0.5° C./h to 5° C./h. In some embodiments, the cooling rate may be in a range of 1° C./h to 4.5° C./h. In some embodiments, the cooling rate may be in a range of 1.5° C./h to 4° C./h. In some embodiments, the cooling rate may be in a range of 2° C./h to 3.5° C./h. In some embodiments, the cooling rate may be in a range of 2.5° C./h to 3° C./h.

In some embodiments, during a formation process of the amorphous cladding, a monitoring component (e.g., a monitoring component 1140) may be used to monitor parameter(s) related to the amorphous cladding. Further, the controlling component (e.g., a controlling component 1150) may adjust cladding formation parameter(s) in real-time based on the parameter(s) related to the amorphous cladding.

In some embodiments, the parameter(s) related to the amorphous cladding may include, but are not limited to, a growth thickness, a uniformity, a flatness of an outer surface, etc., of the amorphous cladding.

In some embodiments, the cladding formation parameter(s) may include but are not limited to, the constant temperature value, the constant temperature interval, the cooling interval, the cooling rate, a contact time between the optical fiber core and the amorphous melt, or the like.

For example, if a difference in the thickness or the flatness at different positions of the amorphous cladding is higher than a predetermined range, it may indicate that the amorphous cladding is not uniform in thickness or poor in flatness. Correspondingly, the controlling component (e.g., the controlling component 1150) may narrow the cooling interval and reduce the cooling rate, thereby adjusting the thickness or flatness of the amorphous cladding. For example, if the thickness of the amorphous cladding is lower than a predetermined cladding thickness, the controlling component (e.g., the controlling component 1150) may increase the contact time between the optical fiber core and the amorphous melt, thereby adjusting the thickness of the amorphous cladding.

In some embodiments, the cladding formation parameter(s) may be determined and/or adjusted by a machine learning model. In some embodiments, the controlling component (e.g., the controlling component 1150) and/or other processing devices may train the machine learning model based on historical parameter(s) related to amorphous cladding and historical cladding formation parameter(s). An input of the machine learning model may include parameter(s) of the optical fiber core (e.g., a type of the optical fiber core, a size of the optical fiber core, etc.) and the parameter(s) related to the amorphous cladding (e.g., the thickness of the amorphous cladding, the flatness of a surface, etc.), and an output of the machine learning model may include the cladding formation parameter(s).

In some embodiments, the input of the machine learning model may also include the environmental condition (e.g., the humidity, the temperature).

In some embodiments, the controlling component may also dynamically update the parameter(s) of the machine learning model based on updated experimental data, which enhances a comprehensive learning capability of the machine learning model to determine more accurate cladding formation parameter(s).

In some embodiments, the controlling component (e.g., the controlling component 1150) may determine and/or automatically adjust the cladding formation parameter(s) based on the parameter(s) of the optical fiber core, the parameter(s) related to amorphous cladding, and a trained machine learning model, thereby automatically controlling the amorphous cladding in real-time during a growth process of the amorphous cladding. In some embodiments, the cladding formation parameter(s) output by the machine learning model may be adaptively adjusted according to actual situation(s) (e.g., the environmental condition) to adapt to different actual situations.

In some embodiments, the cladding formation parameter(s) may also be determined in other manners. For example, the parameter(s) may be determined based on statistical data, empirical parameter(s), user customization, or the like.

In some embodiments, after the amorphous cladding is formed around the periphery of the optical fiber core, the optical fiber core with the amorphous cladding formed around the periphery may be lifted out of the amorphous melt at a predetermined lifting rate.

The predetermined lifting rate may affect the quality of the amorphous cladding, which in turn may affect the quality of a subsequently prepared crystal cladding. For example, a relatively low predetermined lifting rate may cause the amorphous cladding to crystallize while being lifted out of the amorphous melt, which in turn may affect the quality of the amorphous cladding. However, if the predetermined lifting rate is relatively high, the fiber core with amorphous cladding formed around the periphery may crack due to a relatively large temperature gradient caused by the rapid lifting, which in turn may affect the quality of the amorphous cladding. Therefore, in some embodiments, the predetermined lifting rate may be controlled within a predetermined range to ensure the quality of the amorphous cladding. In some embodiments, the predetermined lifting rate may be in a range of 200 mm/h to 3000 mm/h. In some embodiments, the predetermined lift rate may be in a range of 300 mm/h to 2500 mm/h. In some embodiments, the predetermined lifting rate may be in a range of 400 mm/h to 2000 mm/h. In some embodiments, the predetermined lifting rate may be in a range of 500 mm/h to 1500 mm/h. In some embodiments, the predetermined lifting rate may be in a range of 600 mm/h to 1300 mm/h. In some embodiments, the predetermined lifting rate may be in a range of 700 mm/h to 1200 mm/h. In some embodiments, the predetermined lifting rate may be in a range of 800 mm/h to 1100 mm/h. In some embodiments, the predetermined lifting rate may be in a range of 900 mm/h to 1000 mm/h.

In some embodiments, a post-heating process may be performed on the optical fiber core formed with the amorphous cladding during the lifting process. In some embodiments, the post-heating process may be performed by a post-heating assembly (e.g., a resistive heating assembly, an inductive heating assembly, etc.). The post-heating process may create a temperature field to prevent the optical fiber core with the amorphous cladding formed around the periphery from cracking due to an excessively large temperature gradient when the optical fiber core is lifted out of the amorphous melt. In embodiments of the present disclosure, the terms “temperature field” and “temperature gradient” may be used interchangeably unless otherwise noted. In some embodiments, the temperature field formed in the post-heating process may be a temperature field with an increasing temperature gradient along an axial direction (i.e., a lifting direction), a temperature field with a decreasing temperature gradient along the axial direction, or a temperature field with a constant temperature gradient along the axial direction.

In 1050, a crystallization process may be performed on the amorphous cladding to obtain the crystal cladding. In some embodiments, operation 1050 may be performed by a crystal cladding preparation component 1130.

In some embodiments, a crystallization process may include a process in which an amorphous phase material may convert into a crystalline phase material. In some embodiments, the crystallization process may include an arc discharge process. In some embodiments, the arc discharge process refers to performing the crystallization process on the amorphous cladding using a high temperature generated by an arc discharge plasma. In some embodiments, the controlling component may adjust a temperature generated by the arc discharge plasma by adjusting a voltage or a current. In some embodiments, the temperature (which may be referred to as a “crystallization temperature”) may be lower than the melting temperature of the amorphous cladding to prevent re-melting of the amorphous cladding. In some embodiments, the arc discharge process may be performed by an arc discharge assembly (e.g., an arc discharge assembly 1131). The arc discharge process can concentrate energy, heat up quickly, enhance crystallization efficiency, and a shape of the arc discharge can be adapted to a shape (e.g., a columnar shape) of the optical fiber core formed with the amorphous cladding, ensuring a more thorough crystallization process and improving consistency of the crystallization process.

In some embodiments, the crystallization process may also include other modes of processes, for example, a heating process, a laser annealing process, or the like.

The following description takes performing the crystallization process on the YAG amorphous cladding to obtain a YAG crystal cladding as an example.

In some embodiments, to improve an efficiency of the crystallization process and to ensure the quality of the crystal cladding, a temperature of the crystallization process may be controlled within a predetermined range. In some embodiments, the temperature of the crystallization process may be in a range of 800° C. to 1500° C. In some embodiments, the temperature of the crystallization process may be in a range of 1000° C. to 1500° C. In some embodiments, the temperature of the crystallization process may be in a range of 1050° C. to 1450° C. In some embodiments, the temperature of the crystallization process may be in a range of 1100° C. to 1400° C. In some embodiments, the temperature of the crystallization process may be in a range of 1150° C. to 1350° C. In some embodiments, the temperature of the crystallization process may be in a range of 1200° C. to 1300° C.

In some embodiments, a processing time of the crystallization process may be determined based on the thickness of the amorphous cladding.

In some embodiments, flowing oxygen may be introduced while performing the crystallization process on the amorphous cladding to avoid oxygen defects in the crystal cladding, thereby further improving the quality of the crystal cladding.

In some embodiments, an oxygen-flowing rate may be controlled within a predetermined range to ensure the quality of the crystal cladding. In some embodiments, the oxygen-flowing rate may be in a range of 1 L/min to 20 L/min. In some embodiments, the oxygen-flowing rate maybe in a range of 2 L/min to 19 L/min. In some embodiments, the oxygen-flowing rate maybe in a range of 3 L/min to 18 L/min. In some embodiments, the oxygen-flowing rate maybe in a range of 4 L/min to 17 L/min. In some embodiments, the oxygen-flowing rate may be in a range of 5 L/min to 16 L/min. In some embodiments, the oxygen-flowing rate maybe in a range of 6 L/min to 15 L/min. In some embodiments, the oxygen-flowing rate maybe in a range of 7 L/min to 14 L/min. In some embodiments, the oxygen-flowing rate maybe in a range of 8 L/min to 13 L/min. In some embodiments, the oxygen-flowing rate maybe in a range of 9 L/min to 12 L/min. In some embodiments, the oxygen-flowing rate maybe in a range of 10 L/min to 11 L/min.

In some embodiments, a crystallizing agent layer may be deposited around the periphery of the amorphous cladding and the crystallization process may be performed on an amorphous cladding deposited with the crystallizing agent layer.

In some embodiments, a crystallizing agent may include but is not limited to, MgO, Ga₂O₃, Cr₂O₃, ZrO₂, La₂O₃, or the like.

In some embodiments, a suspension may be formed by mixing the crystallizing agent with ethanol or water at a predetermined mass ratio. Further, the amorphous cladding may be submerged in the suspension to deposit the crystallizing agent layer around the periphery of the amorphous cladding. In some embodiments, the crystallizing agent layer refers to a liquid film comprising a crystallizing agent formed by the attachment of the suspension to the periphery of the amorphous cladding.

In some embodiments, to make the crystallizing agent layer stably deposited around the periphery of the amorphous cladding such that the crystallization process may be performed to obtain a high-quality crystal cladding, the predetermined mass ratio may be controlled within a predetermined range. In some embodiments, the predetermined mass ratio may be in a range of 1:2 to 1:26. In some embodiments, the predetermined mass ratio may be in a range of 1:3 to 1:24. In some embodiments, the predetermined mass ratio may be in a range of 1:4 to 1:22. In some embodiments, the predetermined mass ratio may be in a range of 1:5 to 1:20. In some embodiments, the predetermined mass ratio may be in a range of 1:6 to 1:18. In some embodiments, the predetermined mass ratio may be in a range of 1:7 to 1:16. In some embodiments, the predetermined mass ratio may be in a range of 1:8 to 1:14. In some embodiments, the predetermined mass ratio may be in a range of 1:9 to 1:12. In some embodiments, the predetermined mass ratio may be in a range of 1:10 to 1:11.

In the crystallization process, the optical fiber core may be used as a seed layer or a substrate for the crystallization process of the amorphous cladding, so that the crystallization process may be performed from an outer surface of the optical fiber core (or an inner surface of the amorphous cladding) to an outer surface of the amorphous cladding. By introducing the crystallizing agent layer, the crystallization process may be performed from the outer surface of the amorphous cladding to the inner surface of the amorphous cladding (or the outer surface of the optical fiber core). That is to say, by introducing the crystallizing agent layer, the crystallization process of the amorphous cladding may be performed simultaneously from the inner surface and the outer surface of the amorphous cladding to a middle part of the amorphous cladding, which can accelerate the crystallization process of the amorphous cladding, shorten crystallization time, and improve crystallization efficiency.

In some embodiments, after the crystallization process of the amorphous cladding, an outer periphery of the crystal cladding may be cleaned to remove a residual crystallizing agent layer around the outer periphery of the crystal cladding. In some embodiments, a cleaning manner may include but is not limited to, immersion, ultrasonic oscillation, or the like.

It should be noted that the descriptions of process 1000 are intended to be exemplary and illustrative only and do not limit the scope of application of the present disclosure. For those skilled in the art, various modifications and changes may be made to process 1000 under the guidance of the present disclosure. However, these modifications and changes remain within the scope of the present disclosure. For example, process 1000 may also be used to prepare other claddings and is not limited to the YAG crystal cladding. As another example, after the raw material is melted to form the raw material melt, the raw material melt may be cooled rapidly at a relatively high cooling rate to form the amorphous material.

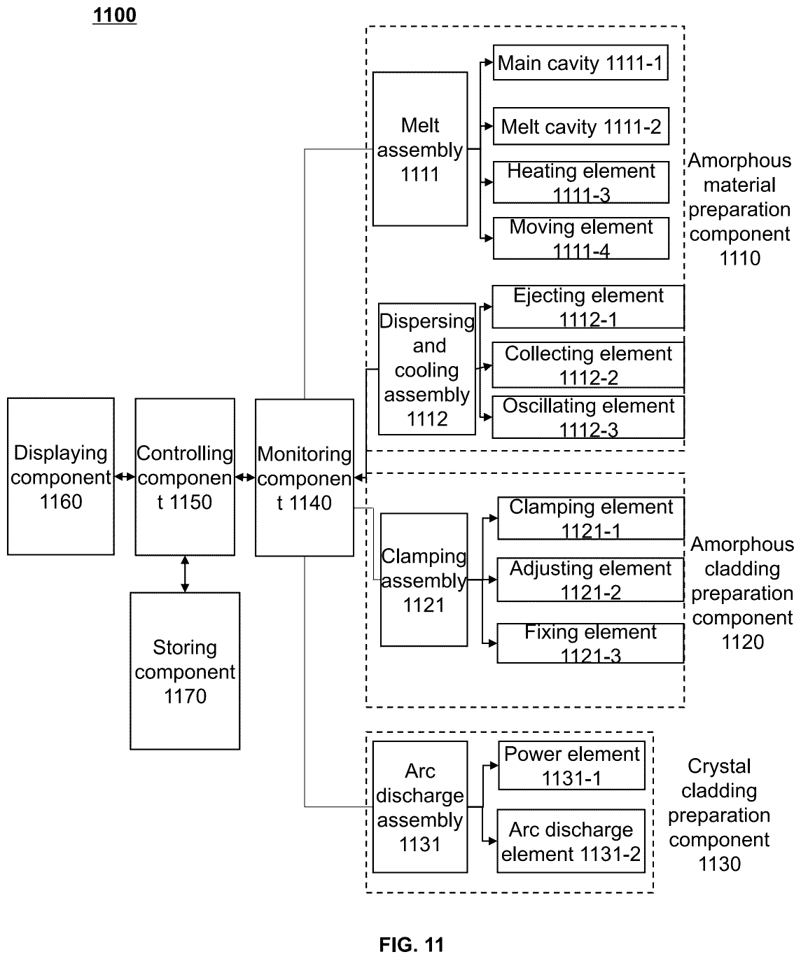

FIG. 11 is a schematic diagram illustrating an exemplary device for preparing a crystal cladding according to some embodiments of the present disclosure.

In some embodiments, a device 1100 for preparing a crystal cladding may include the amorphous material preparation component 1110, the amorphous cladding preparation component 1120, and the crystal cladding preparation component 1130.

The amorphous material preparation component 1110 may be used to prepare an amorphous material. More descriptions regarding preparing the amorphous material may be found elsewhere (e.g., FIG. 10 and the related descriptions thereof) in the present disclosure.

In some embodiments, the amorphous material preparation component 1110 may include the melt assembly 1111 and the dispersing and cooling assembly 1112.

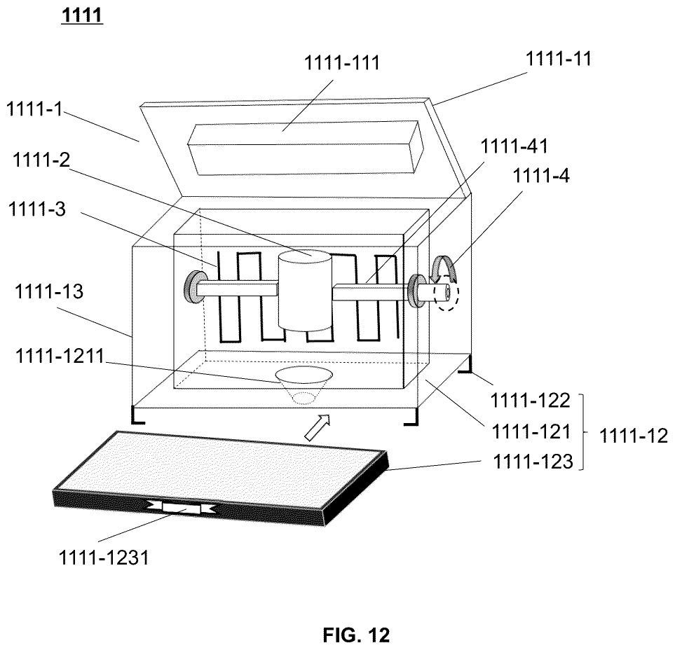

In some embodiments, the melt assembly 1111 may be used to melt a raw material to form a raw material melt. In some embodiments, the melt assembly 1111 may include a main cavity 1111-1, a melt cavity 1111-2, a heating element 1111-3, and a moving element 1111-4. More description regarding the melt assembly may be found in FIG. 12 and the related descriptions thereof.

In some embodiments, the dispersing and cooling assembly 1112 may be used to perform a dispersing and cooling process on the raw material melt to form the amorphous material. In some embodiments, the dispersing and cooling assembly 1112 may include an ejecting element 1112-1, a collecting element 1112-2, and an oscillating element 1112-3. More description regarding the dispersing and cooling assembly may be found in FIG. 13 and the related descriptions thereof.

The amorphous cladding preparation component 1120 may be used to melt the amorphous material to form an amorphous melt, submerge an optical fiber core in the amorphous melt, and form an amorphous cladding around a periphery of the optical fiber core based on the amorphous melt and the optical fiber core. More descriptions regarding forming the amorphous cladding may be found elsewhere (e.g., FIG. 10 and the related descriptions thereof) in the present disclosure.

In some embodiments, the amorphous cladding preparation component 1120 may include a clamping assembly 1121 and a cladding preparation cavity (not shown in the figures).

In some embodiments, the cladding preparation cavity may be used to melt the amorphous material to form the amorphous melt.

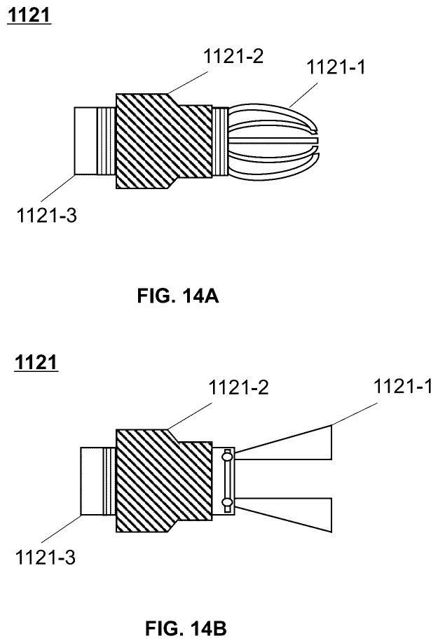

In some embodiments, the clamping assembly 1121 may be used to clamp the optical fiber core and submerge the optical fiber core in the amorphous melt. In some embodiments, the clamping assembly 1121 may include a clamping element 1121-1, an adjusting element 1121-2, and a fixing element 1121-3. More descriptions regarding the clamping assembly may be found in FIG. 14A and FIG. 14B and the related descriptions thereof.

The crystal cladding preparation assembly 1130 may be used to perform a crystallization process on the amorphous cladding to obtain a crystal cladding. More descriptions regarding performing the crystallization process on the amorphous cladding to obtain the crystal cladding may be found elsewhere (e.g., FIG. 10 and the related descriptions thereof) in the present disclosure.

In some embodiments, the crystal cladding preparation assembly 1130 may include an arc discharge assembly 1131.

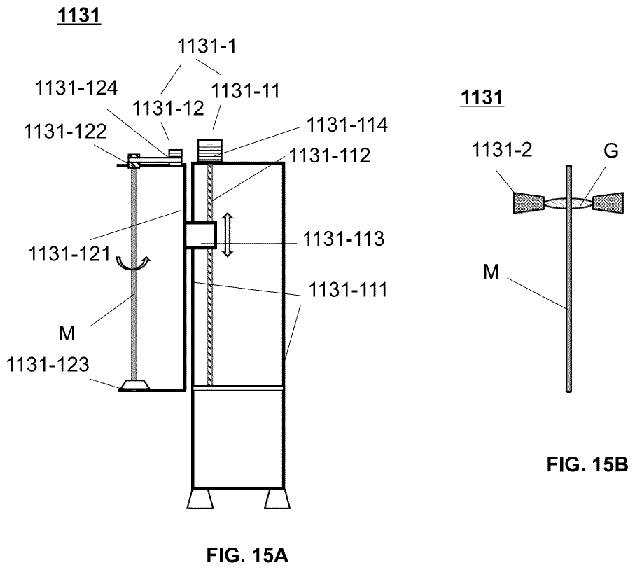

In some embodiments, the arc discharge assembly 1131 may be used to perform an arc discharge process on the amorphous cladding. In some embodiments, the arc discharge assembly 1131 may include a power element 1131-1 and an arc discharge element 1131-2. More description regarding the arc discharge assembly may be found in FIG. 15A and FIG. 15B and the related descriptions thereof.

In some embodiments, the device 1100 for preparing the crystal cladding may further include a monitoring component 1140 and a controlling component 1150. The monitoring component 1140 may be used to monitor parameter(s) related to the amorphous cladding. The controlling component 1150 may be used to adjust cladding formation parameter(s) in real-time based on parameter(s) related to the amorphous cladding. In some embodiments, the controlling component 1150 may be used to train the machine learning model described above. More descriptions regarding the parameter(s) related to the amorphous cladding, adjusting the cladding formation parameter(s) based on the parameter(s) in real-time, and training the machine learning model may be found elsewhere (e.g., FIG. 10 and the related descriptions thereof) in the present disclosure.

In some embodiments, the device 1100 for preparing the crystal cladding may further include a displaying component 1160 for displaying melting-related parameter(s), parameter(s) of the cooling process, the parameter(s) related to the amorphous cladding, or the like.

In some embodiments, the device 1100 for preparing the crystal cladding may further include a storing component 1170 for storing experimental data, statistical data, machine learning models, or the like.

It should be noted that the descriptions of the device 1100 for preparing the crystal cladding are for the purpose of exemplification and illustration only and does not limit the scope of the present disclosure. For those skilled in the art, various modifications and changes may be made to the device 1100 for preparing the crystal cladding under the guidance of the present disclosure. However, these modifications and changes remain within the scope of the present disclosure.

FIG. 12 is a schematic diagram illustrating an exemplary structure of a melt assembly according to some embodiments of the present disclosure.

As shown in FIG. 12, the melt assembly 1111 may include a main cavity 1111-1, a melt cavity 1111-2, a heating element 1111-3, and a moving element 1111-4.

In some embodiments, the main cavity 1111-1 may be a place to accommodate each element of the melt assembly 1111. In some embodiments, a shape of the main cavity 1111-1 may include but is not limited to, a cylindrical shape, a rectangular shape, a cubic shape, etc. In some embodiments, the main cavity 1111-1 may be sealed.

In some embodiments, the main cavity 1111-1 may be provided with an insulation layer for insulating the main cavity 1111-1. In some embodiments, a material of the insulation layer may include, but is not limited to, an insulation material such as graphite felt, zirconia felt, an insulation brick, or the like.

In some embodiments, the main cavity 1111-1 may include a cavity upper cover 1111-11, a cavity lower cover 1111-12, and a middle cavity 1111-13. In some embodiments, shapes and sizes of the cavity upper cover 1111-11 and the cavity lower cover 1111-12 may match the middle cavity 1111-13, thereby sealing the main cavity 1111-1.

In some embodiments, the cavity upper cover 1111-11 may be provided with a boss 1111-111 on an inner side of the cavity upper cover 1111-11. In some embodiments, the cavity upper cover 1111-11 and/or the boss 1111-111 may be made of an insulating material. In some embodiments, a size of the boss 1111-111 may match an upper part of the middle cavity 1111-13 to reduce an excess space in the middle part 1111-13 and improve an insulation effect.

In some embodiments, the cavity lower cover 1111-12 may be made of an insulating material. In some embodiments, the cavity lower cover 1111-12 may include a cavity lower plate 1111-121, a cavity lower cover support 1111-122, and a cavity lower cover body 1111-123.

In some embodiments, the cavity lower plate 1111-121 may be provided with an opening 1111-1211 penetrating through the cavity lower plate 1111-121 for a raw material melt to pass through, facilitating a subsequent dispersing and cooling process performed on the raw material melt to form an amorphous material.

In some embodiments, the cavity lower cover support 1111-122 may be uniformly or non-uniformly distributed on the cavity lower plate 1111-121.

In some embodiments, the cavity lower cover body 1111-123 may be made of an insulating material. The cavity lower cover body 1111-123 may be provided with a pull tab 1111-1231. In some embodiments, the pull tab 1111-1231 may be used to place the cavity lower cover body 1111-123 on a lower part of the cavity lower plate 1111-121 and cause the cavity lower cover body 1111-123 to snap onto the cavity lower cover support 1111-122, thereby sealing the middle cavity 1111-13. In some embodiments, the cavity lower cover body 1111-123 may be removed from the cavity lower cover support 1111-122 using the pull tab 1111-1231, facilitating a passage of the raw material melt through the opening 1111-1211 for the subsequent dispersing and cooling process.

In some embodiments, the melt cavity 1111-2 may be used to place and melt the raw material. In some embodiments, the melt cavity 1111-2 may be located inside the main cavity 1111-1. In some embodiments, a material of the melt cavity 1111-2 may include but is not limited to at least one of graphite, quartz, alumina, zirconia, iridium, platinum, tungsten, tantalum, or molybdenum.

In some embodiments, the heating element 1111-3 may be used to heat the melt cavity 1111-2 to melt the raw material. In some embodiments, a heating mode of the heating element 1111-3 may include but is not limited to resistance heating, induction heating, or the like. In some embodiments, when the heating element 1111-3 is a resistance heating element, the heating element 1111-3 may include but is not limited to a high resistance graphite, a molybdenum silica (MoSi2) rod, a nickel-chromium (Ni—Cr) wire, a ferro-chromium aluminum (Fe—Cr—Al) wire, a nickel-iron (Ni—Fe) wire, a nickel-copper (Ni—Cu) wire, a silicon carbide (SiC) rod, or the like.

In some embodiments, the moving element 1111-4 may be used to drive the melt cavity 1111-2 to move. In some embodiments, the moving element 1111-4 may be used to drive the melt cavity 1111-2 to tilt at a predetermined angle, causing the raw material melt inside the melt cavity 1111-2 to dump out to pass through the opening 1111-1211.

In some embodiments, the moving element 1111-4 may include a connecting rod 1111-41. In some embodiments, the middle cavity 1111-13 may be provided with a through-hole through which the connecting rod 1111-41 passes. One end of the connecting rod 1111-41 may be fixedly connected to the melt cavity 1111-2, and the other end may pass through the through-hole on the middle cavity 1111-13.

In some embodiments, the connecting rod 1111-41 may be rotated manually (e.g., by a wrench) to drive the melt cavity 1111-2 to move.

In some embodiments, the moving element 1111-4 may also include a driving element (not shown in the figures). The driving element may be used to drive the connecting rod 1111-41 to move, thereby driving the melt cavity 1111-2 to move.

FIG. 13 is a schematic diagram illustrating an exemplary structure of a dispersing and cooling assembly according to some embodiments of the present disclosure.

As shown in FIG. 13, the dispersing and cooling assembly 1112 may include an ejecting element 1112-1 and a collecting element 1112-2.

In some embodiments, the ejecting element 1112-1 may be used to eject a fluid. In some embodiments, the ejecting element 1112-1 may include an ejecting body (not shown in the figures) and an ejection port 1112-11. In some embodiments, as shown in FIG. 13, the fluid may be ejected from the ejection port 1112-11 to perform a dispersing and cooling process on a raw material melt R flowing out of the melt assembly 1111 (e.g., the opening 1111-1211) to obtain an amorphous material.

In some embodiments, the collecting element 1112-2 may be used to collect the amorphous material. In some embodiments, the collecting element 1112-2 may include a collecting body 1112-21, a collecting frame 1112-22, and a baffle plate 1112-23.

In some embodiments, the collecting body 1112-21 may be an annular cavity with a hollow interior having a partial opening (as shown by a dashed line L in FIG. 13). In some embodiments, an opening curvature of the collecting body 1112-21 (as shown by the dashed line L in FIG. 13) may be determined based on a distance between the ejection port 1112-11 and the collecting body 1112-21, an ejection angle, an ejection pressure, or the like. In some embodiments, a material of the collecting body 1112-21 may include but is not limited to a material that has a high thermal conductivity graphite such as copper, aluminum, silver, or the like, so that at a portion of fine amorphous melts may be further cooled to form amorphous solid particles.

In some embodiments, a collecting port 1112-211 may be provided on a lower outer side of the annular cavity of the collecting body 1112-21.

In some embodiments, the collecting frame 1112-22 may be provided in a lower part of the collecting port 1112-211 for collecting the amorphous material (e.g., the fine amorphous melts and the amorphous solid particles).

In some embodiments, the baffle plate 1112-23 may be evenly or unevenly disposed on an inner inside of the annular cavity of the collecting body 1112-21, as shown in FIG. 13. In some embodiments, holes 1112-212 may be provided on the baffle plate 1112-23 on the inner side of the collecting body 1112-21 such that the fine amorphous melts and/or the amorphous solid particles (as shown by B in FIG. 13) obtained after a dispersing and cooling process may pass through the holes 1112-212 to enter into an interior of the collecting cavity 1112-21 after being decelerated by colliding with the baffle plate 1112-23, and then enter the collecting frame 1112-22 through the collecting port 1112-211.

In some embodiments, the dispersing and cooling member 1112 may further include an oscillating element 1112-3 for oscillating the amorphous material (e.g., the amorphous melts and the amorphous solid particles) after the dispersing and cooling process during a collecting process, which can prevent the fine amorphous melts and/or the amorphous solid particles from adhering to an inner wall of the dispersing and cooling assembly 1112 (e.g., the collecting body 1112-21), thereby improving a utilization rate of the raw material.

In some embodiments, the oscillating element 1112-3 may be provided on the collecting body 1112-21. In some embodiments, the oscillating element 1112-3 may include, but is not limited to, an oscillator.

FIG. 14A is a schematic diagram illustrating an exemplary structure of a clamping assembly according to some embodiments of the present disclosure. FIG. 14B is a schematic diagram illustrating an exemplary structure of a clamping assembly according to other embodiments of the present disclosure.

In some embodiments, the clamping assembly 1121 may include a clamping element 1121-1, an adjusting element 1121-2, and a fixing element 1121-3.

In some embodiments, the clamping element 1121-1 may include at least two clamping rods. The at least two clamping rods may be evenly disposed at one end of the fixing element 1121-3. In some embodiments, as shown in FIG. 14A, a side of the clamping rod that clamps an optical fiber core may have a curvature. In some embodiments, a side of the clamping rod that clamps the optical fiber core may not have a curvature, as shown in FIG. 14B.

In some embodiments, the adjusting element 1121-2 may match the fixing element 1121-3 to adjust an opening or closing degree of the clamping element 1121-1 to stably clamp the optical fiber core.

In some embodiments, the adjusting element 1121-2 may be disposed around a periphery of the fixing element 1121-3, as shown in FIG. 14A and FIG. 14B. In some embodiments, the periphery of the fixing element 1121-3 may be provided with an external thread, and an inner side of the adjusting element 1121-2 may be provided with an internal thread. The external thread and the internal thread may be adapted to each other. By adjusting (e.g., rotating clockwise or counterclockwise) a screwing-in or screwing-out of the adjusting element 1121-2 on the fixing element 1121-3, one end of the adjusting element 1121-2 may adjust the opening or closing degree of the clamping element 1121-1.

FIG. 15A is a schematic diagram illustrating an exemplary structure of a power element according to some embodiments of the present disclosure. FIG. 15B is a schematic diagram illustrating an exemplary structure of an arc discharge element according to some embodiments of the present disclosure.

In some embodiments, the arc discharge assembly 1131 may include a power element 1131-1 and an arc discharge element 1131-2.

In some embodiments, the power element 1131-1 may be used to drive an optical fiber core M formed with an amorphous cladding for an up-and-down movement and/or rotational movement. In some embodiments, the power element 1131-1 may include an up-and-down movement driving member 1131-11 and a rotational movement driving member 1131-12.

In some embodiments, the up-and-down movement driving member 1131-11 may include a support 1131-111, a screw 1131-112, a slider 1131-113, and a first driving motor 1131-114. The up-and-down movement driving member 1131-11 may be configured to drive the optical fiber core M formed with the amorphous cladding to move up and down.

In some embodiments, the support 1131-111 may be used to support the screw 1131-112, the slider 1131-113, and the first driving motor 1131-114.

In some embodiments, the screw 1131-112 may be provided on the support 1131-111. In some embodiments, the screw 1131-112 may be disposed parallel to some rods of the support 1131-111.

In some embodiments, the slider 1131-113 may be sheathed on the screw 1131-112. In some embodiments, one end of the slider 1131-113 may be connected (e.g., welded) to the rotational movement driving member 1131-12 (e.g., a support bracket 1131-121).

In some embodiments, the first driving motor 1131-114 may be used to drive the screw 1131-112 to rotate, thereby causing the slider 1131-113 to move up and down along the screw 1131-112, which further drives the rotational movement driving member 1131-12 to move up and down.

In some embodiments, the rotational movement driving member 1131-12 may include the support bracket 1131-121, a connecting member 1131-122, a stabilizing member 1131-123, and a second driving motor 1131-124. The rotational movement driving member 1131-12 may be configured to drive the optical fiber core M formed with the amorphous cladding to rotate.

In some embodiments, the support bracket 1131-121 may be used to support and stabilize the optical fiber core M formed with the amorphous cladding. In some embodiments, a height of the support bracket 1131-121 may be adapted to the optical fiber core M formed with the amorphous cladding.

In some embodiments, the connecting member 1131-122 may be used to connect and secure the optical fiber core M formed with the amorphous cladding. In some embodiments, the connecting member 1131-122 may be connected (e.g., welded) to the support bracket 1131-121. In some embodiments, a structure of the connecting member 1131-122 may be the same or different from the clamping assembly 1121.

In some embodiments, the stabilizing member 1131-123 may be connected (e.g., welded) to the support bracket 1131-121. In some embodiments, the stabilizing member 1131-123 may be provided with a recessed hole that is adapted to the optical fiber core M formed with the amorphous cladding for stabilizing the optical fiber core M formed with the amorphous cladding and preventing the optical fiber core M from deflection.

In some embodiments, the second driving motor 1131-124 may be used to drive the connecting member 1131-122 to rotate via a transmission member (e.g., a belt, a rack, etc.), thereby driving the optical fiber core M formed with the amorphous cladding to rotate.

In some embodiments, the arc discharge element 1131-2 may be used to perform an arc discharge process on the amorphous cladding to form a high-temperature region G around a periphery of the amorphous cladding.

### Example 1

Y₂O₃ powder and Al₂O₃ powder both with a purity greater than 99.9% were weighed in accordance with a stoichiometric ratio, and put into a crucible after mixing evenly. The crucible was placed in a muffle furnace for calcination at a temperature in a range of 1400° C. to 1700° C. for a calcination time of 5 h to 25 h, and YAG polycrystalline powder was produced.

The YAG polycrystalline powder was subjected to a heating process at a heating rate of 1° C./min to 12° C./min, and flowing argon and nitrogen with a flow rate of 1 L/min to 5 L/min were introduced during the heating process. The temperature was increased to a range of 1900° C. to 2100° C., and the heat was insulated for 2 h to 12 h to obtain a YAG melt.

The YAG melt was poured out, an ejecting element was activated, and the YAG melt was dispersed and cooled by liquid nitrogen ejected by the ejecting element, so that fine amorphous YAG melts and amorphous YAG solid particles were obtained. An ejection angle was 20°-70°, an ejection pressure was 0.1 MPa to 2.5 MPa, and a distance between an ejection port of the ejecting element and the YAG melt was between 3 cm and 12 cm. The amorphous YAG melt and the amorphous YAG solid particles were oscillated during the dispersing and cooling process.

The amorphous YAG melt and the amorphous YAG solid particles were melted at a temperature in a range of 1500° C. to 1800° C. and insulated for 2 h to 15 h to obtain an amorphous YAG melt.

A YAG-doped single-crystal optical fiber core was clamped using a clamping assembly and submerged in the amorphous YAG melt at an angle of 0° to 15° relative to a horizontal plane. A temperature of the amorphous YAG melt was maintained in a range of 1500° C. to 1800° C., causing the amorphous YAG melt to adhered to an outer periphery of the YAG-doped single-crystal optical fiber core, forming an amorphous YAG cladding.

A YAG-doped single-crystal optical fiber core with an amorphous YAG cladding formed around the periphery was lifted out of the amorphous YAG melt at a lifting rate of 200 mm/h to 3000 mm/h and submerged in a suspension to deposit a crystallizing agent layer around the periphery of the amorphous YAG cladding. The suspension was formed by mixing MgO with ethanol in a mass ratio of 1:2 to 1:26. The amorphous YAG cladding deposited with the crystallizing agent layer was heated for a crystallization process at a crystallization temperature of 1000° C. to 1500° C. for a crystallization time of 2 to 5 days, and a YAG crystal cladding was obtained. During the crystallization process, flowing oxygen with a flow rate of 1 L/min to 20 L/min was introduced. The YAG crystal cladding was placed in deionized water and ultrasonically oscillated to remove a residual crystallizing agent layer around the periphery of the YAG crystal cladding.

Beneficial effects provided by the embodiments of the present disclosure may include the followings. (1) A doped YAG single crystal fiber core may be prepared by an acid solution immersing manner and the doped YAG single crystal fiber core may be polished, accordingly, a doped YAG single crystal fiber core with a uniform diameter can be prepared, a surface smoothness of the doped YAG single crystal fiber core can be improved, and a surface roughness of the doped YAG single crystal fiber core can be reduced, thereby reducing a transmission loss of the doped YAG single crystal fiber and improving a transmission quality of the doped YAG single crystal fiber. (2) A doped YAG single crystal fiber may be prepared by growing a YAG single crystal fiber cladding on a surface of the doped YAG single crystal fiber core, and the doped YAG single crystal fiber has a smooth surface, a uniform diameter, and a relatively high thermal conductivity and transmission quality. (3) The process for preparing the doped YAG single crystal fiber is simple and easy to operate, which can improve a preparation efficiency of the doped YAG single crystal fiber; (4) The method for preparing a crystal cladding including forming an amorphous cladding around a periphery of the single crystal fiber core and performing a crystallization process on the amorphous cladding is simple and convenient without introducing impurities (e.g., fluxes) during a preparation process, which is non-polluting with low energy consumption. (5) The method for preparing a crystal cladding including forming an amorphous cladding around a periphery of the single crystal fiber core and performing a crystallization process on the amorphous cladding is performed under normal pressure condition. (6) The device for preparing the crystal cladding including an amorphous material preparation component, an amorphous cladding preparation component and a crystal cladding preparation component is simple, does not require a high-pressure condition and a high-pressure device, and is easy to operate and maintain. (7) A high-quality amorphous material can be obtained through a rapid dispersing and cooling process by ejecting a fluid to a melt, thereby preparing a high-quality amorphous cladding and a crystal cladding. (8) The quality of the crystal cladding is enhanced by monitoring, controlling, and adjusting preparation parameter(s) throughout the preparation process. (9) By introducing the crystallizing agent layer, the crystallization process of the amorphous cladding can be performed from the inner surface and the outer surface of the amorphous cladding to the middle part of the amorphous cladding simultaneously, which can speed up the crystallization process of the amorphous cladding, shorten the crystallization time, and improve an efficiency of the crystallization process.

It should be noted that the beneficial effects that may arise from different embodiments may be different. In different embodiments, the beneficial effects may be a combination of any one or more of the above, or any other possible beneficial effects that may be obtained.

The basic concepts have been described above, and it is apparent to those skilled in the art that the foregoing detailed disclosure serves only as an example and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe embodiments of the present disclosure. Words such as “an embodiment,” “one embodiment,” and/or “some embodiment” refer to a feature, structure, or characteristic associated with at least one embodiment of the present disclosure. Accordingly, it should be emphasized and noted that “an embodiment,” or “one embodiment,” or “an alternative embodiment” mentioned two or more times in different places in the present disclosure do not necessarily refer to the same embodiment. In addition, certain features, structures, or characteristics in one or more embodiments of the present disclosure may be suitably combined.

Additionally, unless expressly stated in the claims, the order of the processing elements and sequences, the use of numerical letters, or the use of other names as described in the present disclosure are not intended to qualify the order of the processes and methods of the present disclosure. While some embodiments of the invention that are currently considered useful are discussed in the foregoing disclosure by way of various examples, it should be appreciated that such details serve only illustrative purposes and that additional claims are not limited to the disclosed embodiments, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or a mobile device.

Similarly, it should be noted that in order to simplify the presentation of the disclosure of the present disclosure, and thereby aid in the understanding of one or more embodiments of the present disclosure, the foregoing descriptions of embodiments of the present disclosure sometimes group multiple features in a single embodiment, accompanying drawings, or a description thereof. However, this manner of disclosure does not imply that the subject matters of the present disclosure require more features than those mentioned in the claims. Rather, claimed subject matters may lie in less than all features of a single foregoing disclosed embodiment.

Some embodiments use numbers to describe the number of components, attributes, and it should be understood that such numbers used in the description of the embodiments are modified in some examples by the modifiers such as “about,” “approximately,” or “substantially,” Unless otherwise noted, the terms “about,” “approximate,” or “substantially” indicate that a ±20% variation in the stated number is allowed. Correspondingly, in some embodiments, the numerical parameters used in the present disclosure and claims are approximations, which are subject to change depending on the desired characteristics of individual embodiments. In some embodiments, the numerical parameters should take into account the specified number of valid digits and employ general place-keeping. While the numerical domains and parameters used to confirm the breadth of their ranges in some embodiments of the present disclosure are approximations, in specific embodiments, such values are set to be as precise as possible within a feasible range.

For each patent, patent application, patent application disclosure, and other material cited in the present disclosure, such as articles, books, specification sheets, publications, documents, etc., the entire contents of each of which are hereby incorporated herein by reference. Except for application history documents that are inconsistent with or create a conflict with the contents of the present disclosure, and except for documents that limit the broadest scope of the claims of the present disclosure (currently or hereafter appended to the present disclosure). It should be noted that in the event of any inconsistency or conflict between the descriptions, definitions, and/or use of terminologies in the materials appended to the present disclosure and those outlined in the present disclosure, the descriptions, definitions, and/or use of terms in the present disclosure shall prevail.

Finally, it should be understood that the embodiments described herein are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A method for preparing a crystal cladding, comprising:
preparing an amorphous material;
melting the amorphous material to form an amorphous melt;
submerging an optical fiber core in the amorphous melt;
forming an amorphous cladding around a periphery of the optical fiber core based on the amorphous melt and the optical fiber core; and
obtaining the crystal cladding by performing a crystallization process on the amorphous cladding.

2. The method of claim 1, wherein
a melting temperature interval for melting the amorphous material to form the amorphous melt is lower than a melting temperature of the optical fiber core.

3. The method of claim 1, wherein the preparing an amorphous material includes:
melting a raw material to form a raw material melt; and
dispersing and cooling the raw material melt by ejecting a fluid to form the amorphous material.

4. The method of claim 3, wherein an angle between an ejection direction of the fluid and a horizontal plane is in a range of 20° to 70°.

5. The method of claim 3, wherein an ejection pressure of the fluid is in a range of 0.1 MPa to 2.5 MPa.

6. The method of claim 3, wherein a distance between an ejection port of the fluid and the raw material melt is in a range of 3 cm to 12 cm.

7. The method of claim 3, wherein the preparing an amorphous material further includes:
collecting the amorphous material and oscillating the amorphous material when collecting the amorphous material.

8. The method of claim 1, wherein the submerging an optical fiber core in the amorphous melt includes:
submerging the optical fiber core horizontally in the amorphous melt.

9. The method of claim 1, wherein the forming an amorphous cladding around a periphery of the optical fiber core based on the amorphous melt and the optical fiber core includes:
forming the amorphous cladding around the periphery of the optical fiber core at a constant temperature.

10. The method of claim 1, wherein a viscosity of the amorphous melt is adjusted by adjusting a temperature of the amorphous melt.

11. The method of claim 1, further including:
lifting the optical fiber core with the amorphous cladding formed around the periphery out of the amorphous melt at a predetermined lifting rate, wherein when lifting the optical fiber core, perform a post-heating process on the optical fiber core with the amorphous cladding formed around the periphery.

12. The method of claim 11, wherein the predetermined lifting rate is in a range of 200 mm/h to 3000 mm/h.

13. The method of claim 1, wherein the performing a crystallization process on the amorphous cladding includes:
depositing a crystallizing agent layer around a periphery of the amorphous cladding; and
performing the crystallization process on the amorphous cladding deposited with the crystallizing agent.

14. The method of claim 1, wherein a temperature of the crystallization process is lower than a melting temperature of the amorphous cladding.

15. The method of claim 1, wherein the crystallization process includes an arc discharge process, wherein a shape of an arc discharge in the arc discharge process is adapted to a shape of the optical fiber core formed with the amorphous cladding.

16. The method of claim 1, wherein flowing oxygen is introduced during the crystallization process performed on the amorphous cladding.

17. A device for preparing a crystal cladding, comprising:
an amorphous material preparation component, configured to prepare an amorphous material;
an amorphous cladding preparation component, configured to:
melt the amorphous material to form an amorphous melt;
submerge an optical fiber core in the amorphous melt; and
form an amorphous cladding around a periphery of the optical fiber core based on the amorphous melt and the optical fiber core; and
a crystal cladding preparation assembly, configured to perform a crystallization process on the amorphous cladding to obtain a crystal cladding.

18. The device of claim 17, wherein the amorphous material preparation component includes:
a melt assembly, configured to melt a raw material to form a raw material melt; and
a dispersing and cooling assembly, wherein the dispersing and cooling assembly includes:
an ejecting element, configured to disperse and cool the raw material melt by ejecting a fluid to form the amorphous material; and
a collecting element, configured to collect the amorphous material.

19. The device of claim 18, wherein the dispersing and cooling assembly further includes an oscillating element configured to oscillate the amorphous material while collecting the amorphous material.

20. The device of claim 17, wherein the crystal cladding preparation assembly includes an arc discharge assembly configured to perform an arc discharge process on the amorphous cladding for performing the crystallization process.
